(19) United States
(12) Patent Application Publication
(10) Pub. No.: US 2008/0170428 A1
(43) Pub. Date: Jul. 17, 2008

(54) NONVOLATILE SEMICONDUCTOR MEMORY DEVICE AND METHOD OF WRITING INTO THE SAME

(75) Inventor: Kentaro KINOSHITA, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/037,345

(22) Filed: Feb. 26, 2008

Related U.S. Application Data
(63) Continuation of application No. PCT/JP2005/015579, filed on Aug. 26, 2005.

(51) Int. Cl. G11C 11/21

(52) U.S. Cl. 365/148

(57) ABSTRACT

The semiconductor memory device includes a resistance memory element 46 including a common electrode 38, a resistance memory layer 42 which is formed on the common electrode 38 and is switched between a high resistance state and a low resistance state by an application of a voltage, and a plurality of discrete electrodes formed on the resistance memory layer 42. The resistance memory layer 42 includes a plurality of memory regions which discretely and independently memorize the high resistance state or the low resistance state between the common electrode and the plural discrete electrodes 44. Thus, the resistance memory element can be downsized, and the integration of the nonvolatile semiconductor memory device can be improved.

### CROSS REFERENCE TO RELATED APPLICATIONS

This application is a Continuation of International Application No. PCT/JP2005/015579, with an international filing date of Aug. 26, 2005, which designating the United States of America, the entire contents of which are incorporated herein by reference.

### TECHNICAL FIELD

The present invention relates to a semiconductor memory device and a method of writing into the same.

### BACKGROUND

Recently, as a new memory device, a semiconductor memory device called RRAM (Resistance Random Access Memory) is noted. The RRAM uses a resistance memory element which has a plurality of resistance states of different resistance values, which are changed by electric stimulations applied from the outside and whose high resistance state and low resistance state are corresponded to, e.g., information “0” and “1” to be used as a memory element. The RRAM highly potentially has high speed, large capacities, low electric power consumption, etc. and is considered prospective.

The resistance memory element has a resistance memory material whose resistance states are changed by the application of voltages sandwiched between a pair of electrodes. As the typical resistance memory material, oxide materials containing transition metals are known.

The semiconductor memory device using the resistance memory element is disclosed in, e.g., U.S. Pat. No. 6,473,332, A. Beck et al., Appl. Phys. Lett., Vol. 77, p. 139 (2000), W. W. Zhuang et al., Tech. Digest IEDM 2002, p. 193, and I. G. Baek et al., Tech. Digest IEDM 2004, p. 587.

DRAM and SRAM, and FeRAM (Ferroelectric Random Access Memory), which is prospective as a RAM of the next generation, etc. must have areas of above a certain size so as to ensure a difference required for a reading between before and after a rewriting of data, which is one factor blocking their higher integration. MRAM (Magnetoresistive Random Access Memory) has larger current values necessary for the magnetization inversion as the element area is decreased, which limits the cell size in relation with the writing current value, etc. In view of them, memory materials which facilitate the integration increase and a memory device using such memory materials have been required.

### SUMMARY

According to one aspect of the present invention, there is provided a semiconductor memory device comprising: a resistance memory element including: a common electrode; a resistance memory layer which is formed on the common electrode and is switched between a high resistance state and a low resistance state by an application of a voltage; and a plurality of discrete electrodes formed on the resistance memory layer, wherein the resistance memory layer includes a plurality of memory regions for memorizing the high resistance state or the low resistance state between the common electrode and the plurality of discrete electrodes independently of each other.

According to another aspect of the present invention, there is provided a method of writing into a semiconductor memory device comprising: resetting a plurality of memory regions in a high resistance state at once; and then setting an arbitrary one of the plurality of memory regions in a low resistance state, wherein the semiconductor memory device includes a resistance memory element including a common electrode; a resistance memory layer which is formed on the common electrode and is switched between the high resistance state and the low resistance state by an application of a voltage; and a plurality of discrete electrodes formed on the resistance memory layer, wherein the resistance memory layer includes the plurality of memory regions for memorizing the high resistance state or the low resistance state between the common electrode and the plurality of discrete electrodes independently of each other.

According to further another aspect of the present invention, there is provided a method of writing into a semiconductor memory device comprising: when a first memory region is rewritten into a low resistance state with the first memory region and a second memory region being in a high resistance state, applying a first voltage which is higher than a set voltage of a resistance memory element between a common electrode and a first discrete electrode; applying a second voltage which is lower than the set voltage of the resistance memory element between the common electrode and a second discrete electrode; and setting a potential difference between the first voltage and the second voltage lower than a reset voltage of the resistance memory element, when the first memory region is rewritten into the high resistance state with the first memory region and the second memory regions being in the low resistance state, applying a first voltage which is higher than a reset voltage of the resistance memory element between the common electrode and the first discrete electrode; applying a second voltage which is lower than the reset voltage of the resistance memory element between the common electrode and the second discrete electrode; and setting a potential difference between the first voltage and the second voltage smaller than the reset voltage of the resistance memory element, when the first memory region is rewritten into the high resistance state with the first memory region being in the low resistance state and the second memory region being in the high resistance state, applying a voltage which is higher than or equal to the reset voltage of the resistance memory element respectively between the common electrode and the first discrete electrode and between the common electrode and the second discrete electrode, and when the first memory region is written into the low resistance state with the first memory region being in the high resistance state and the second memory region being in the low resistance state, applying a voltage which is higher than or equal to the reset voltage of the resistance memory element respectively between the common electrode and the first discrete electrode and between the common electrode and the second discrete electrode to thereby rewrite the second memory region into the high resistance state; and then applying a voltage which is higher than or equal to the set voltage of the resistance memory element respectively between the common electrode and the first discrete electrode and between the common electrode and the second discrete electrode to thereby rewrite the first memory region and the second memory region into the low resistance state, wherein the semiconductor memory device includes the resistance memory element including the common electrode; a resistance memory layer which is formed on the common electrode and is switched between the high resistance state and the low resistance state by an application of a voltage; and the first and the second discrete electrodes formed on the resistance memory layer, wherein the resistance memory layer includes the first and the second memory regions for memorizing the high resistance state or the low resistance state between the common electrode and the first and the second discrete electrodes independently of each other.

According to further another aspect of the present invention, there is provided a method of writing into a semiconductor memory device comprising: applying a set voltage of a resistance memory element to that of a plurality of discrete electrodes, which is associated with that of a plurality of memory region into which a low resistance state is to be written; and applying to that of the plurality of discrete electrodes, which is associated with that of the plurality of memory regions, into which the low resistance state is not to be written a voltage V which satisfies relations:

V<V_{SET}+2V_{RESET} and V>V_{SET}−2V_{RESET}

wherein the set voltage of the resistance memory element is V_{SET}, and a reset voltage of the resistance memory element is V_{RESET}, wherein the semiconductor memory device includes a resistance memory element including a common electrode; a resistance memory layer which is formed on the common electrode and is switched between the high resistance state and the low resistance state by an application of a voltage; and the plurality of discrete electrodes formed on the resistance memory layer, wherein the resistance memory layer includes the plurality of memory regions for memorizing the high resistance state or the low resistance state between the common electrode and the plurality of discrete electrodes independently of each other.

According to the present invention, a nonvolatile semiconductor memory device comprises a resistance memory element including a common electrode, a resistance memory layer which is formed on the common electrode and is switched between a high resistance state and a low resistance state by an application of a voltage, and a plurality of discrete electrodes formed on the resistance memory layer, and a plurality of memory regions which discretely and independently memorizes the high resistance state or the low resistance state are formed between the common electrode and the plural discrete electrodes, whereby the resistance memory element can be downsized. Thus, the integration of the nonvolatile semiconductor memory device can be improved.

### BRIEF DESCRIPTION OF THE DRAWINGS

FIG. 1 is a graph showing the current-voltage characteristics of the resistance memory element using a bipolar resistance memory material.

FIG. 2 is a graph showing the current-voltage characteristics of the resistance memory element using a unipolar resistance memory material.

FIG. 3 is a graph showing the current-voltage characteristics explaining the forming processing of the resistance memory element.

FIG. 4 is a graph showing the relationship between the voltage at which the forming takes place and the film thickness of the resistance memory layer.

FIG. 5 is a graph showing the result of constant voltage TDDB measurement of the resistance memory element.

FIG. 6 is a graph showing the current-voltage characteristics of the resistance memory element used in investigating the mechanism of the forming.

FIG. 7 is a graph showing the current-voltage characteristics of each piece of the divided resistance memory element.

FIG. 8 is a plan view showing the structure of the nonvolatile semiconductor memory device according to a first embodiment of the present invention.

FIG. 9 is a diagrammatic sectional view showing the structure of the nonvolatile semiconductor memory device according to the first embodiment of the present invention.

FIG. 10 is a circuit diagram showing the structure of the nonvolatile semiconductor memory device according to the first embodiment of the present invention.

FIGS. 11A-11I are sectional views showing the method of manufacturing the nonvolatile semiconductor memory device according to the first embodiment of the present invention.

FIG. 12 is a plan view showing the structure of the nonvolatile semiconductor memory device according to a second embodiment of the present invention.

FIGS. 13A and 13B are diagrammatic sectional views showing the structure of the nonvolatile semiconductor memory device according to the second embodiment of the present invention.

FIG. 14 is a circuit diagram showing the structure of the nonvolatile semiconductor memory device according to the second embodiment of the present invention.

FIGS. 15A-15G are sectional views showing the method of manufacturing the nonvolatile semiconductor memory device according to the second embodiment of the present invention.

FIG. 16 is a circuit diagram showing the method of writing into the nonvolatile semiconductor memory device according to a fourth embodiment of the present invention.

FIG. 17 is a plan view showing the structure of the nonvolatile semiconductor memory device according to a fifth embodiment of the present invention.

FIGS. 18A and 18B are diagrammatic sectional views showing the structure of the nonvolatile semiconductor memory device according to the fifth embodiment of the present invention.

FIG. 19 is a circuit diagram showing the structure of the nonvolatile semiconductor memory device according to the fifth embodiment of the present invention.

### DETAILED DESCRIPTION OF THE EMBODIMENTS

### A First Embodiment

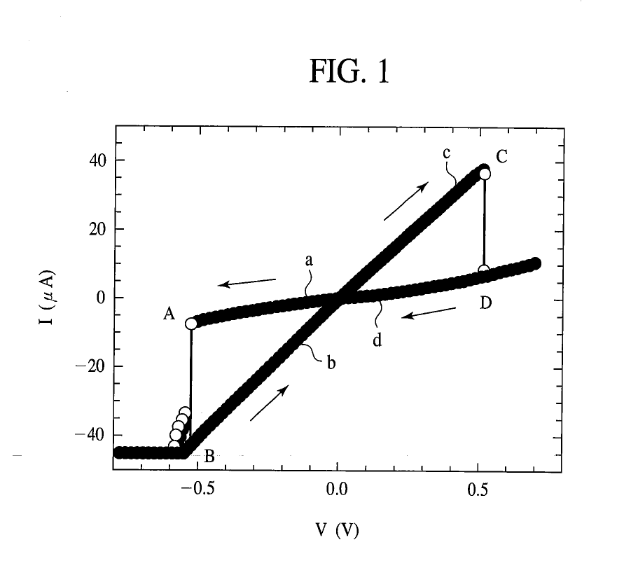

The nonvolatile semiconductor memory device and method of writing into the same according to a first embodiment of the present invention will be explained with reference to FIGS. 1 to 11I.

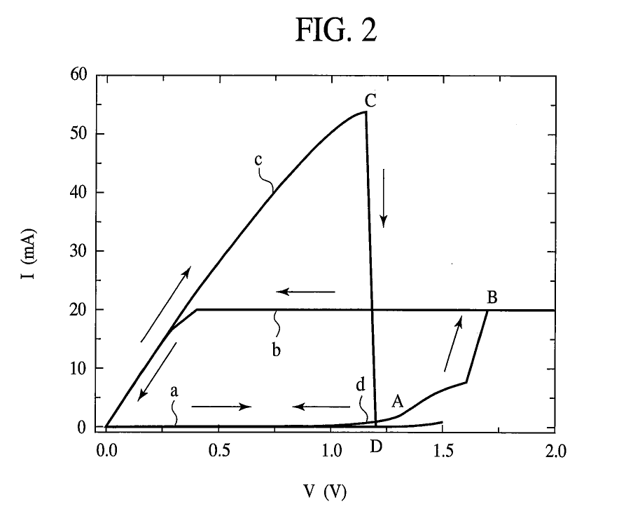

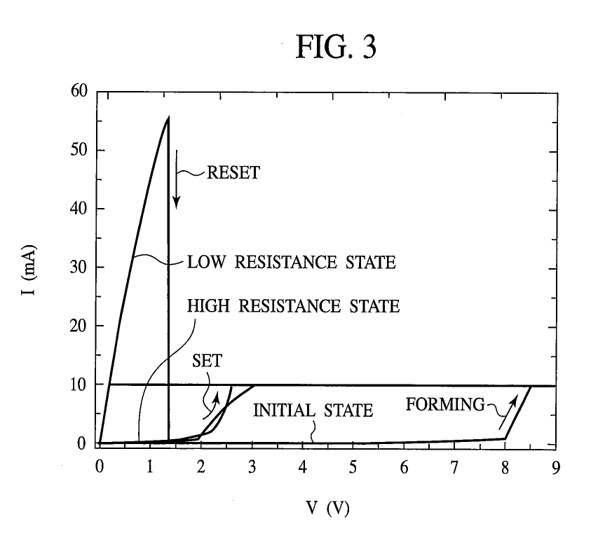

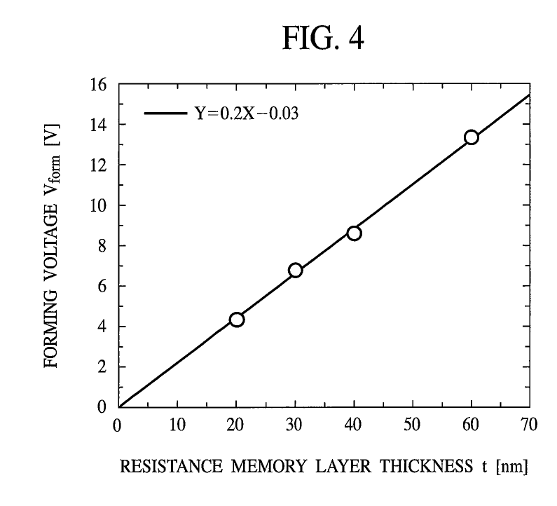

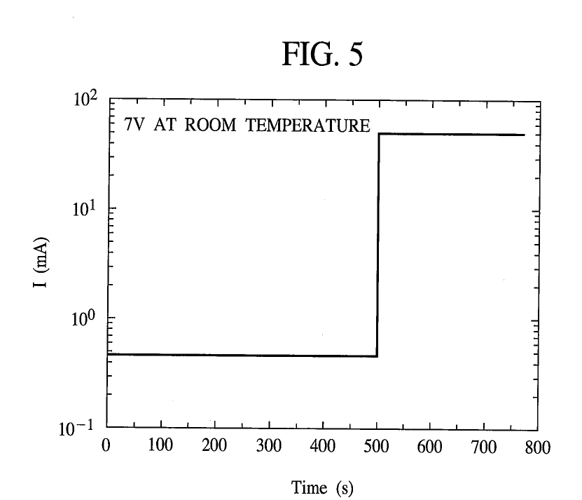

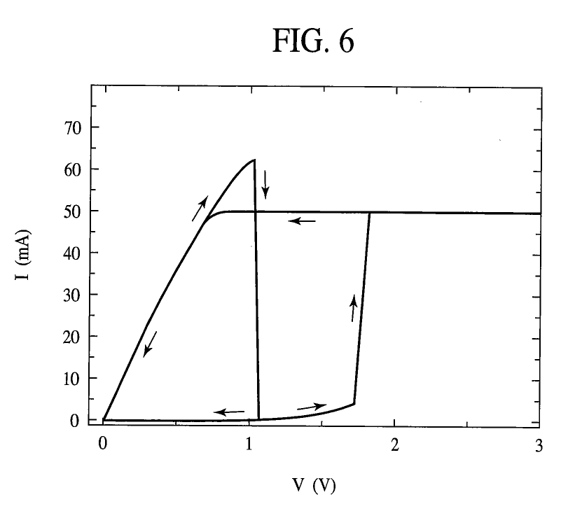

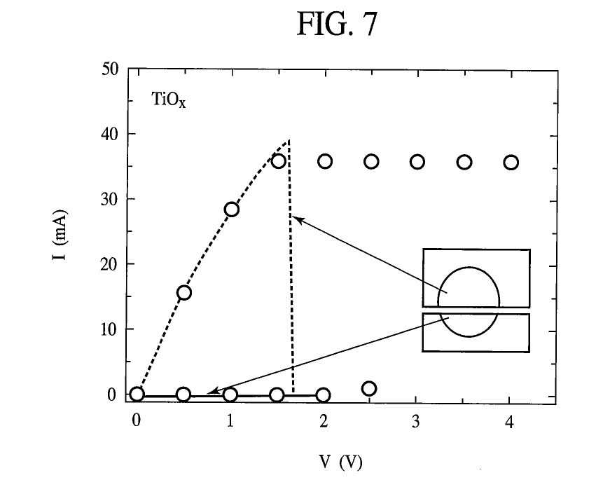

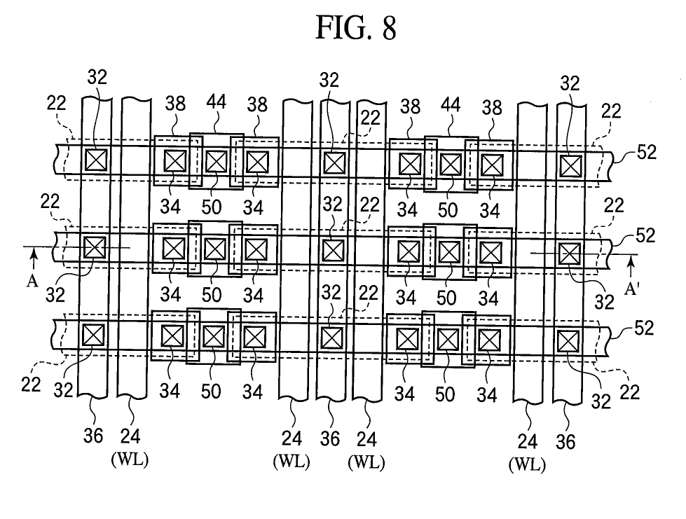

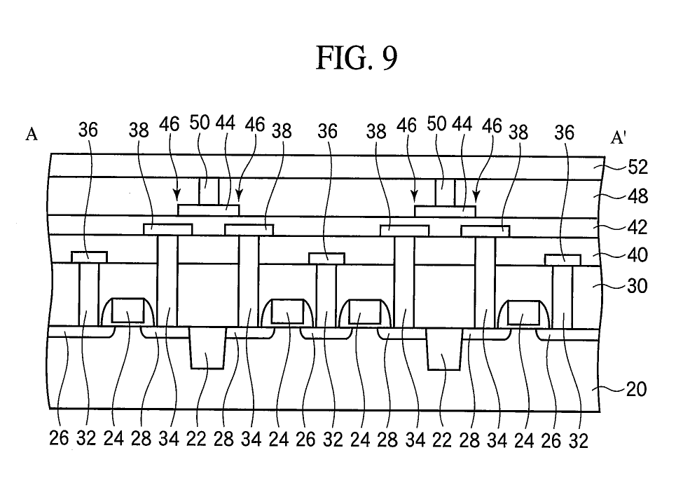

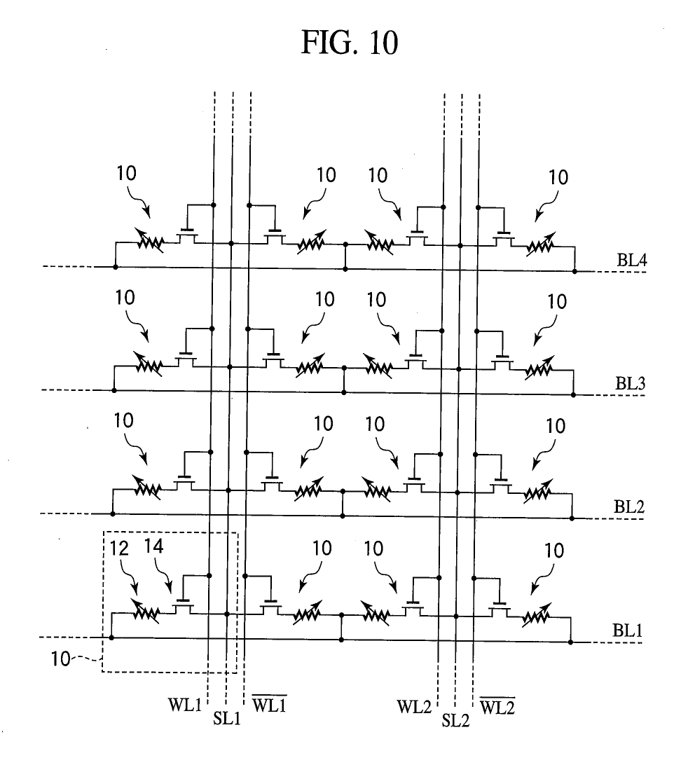

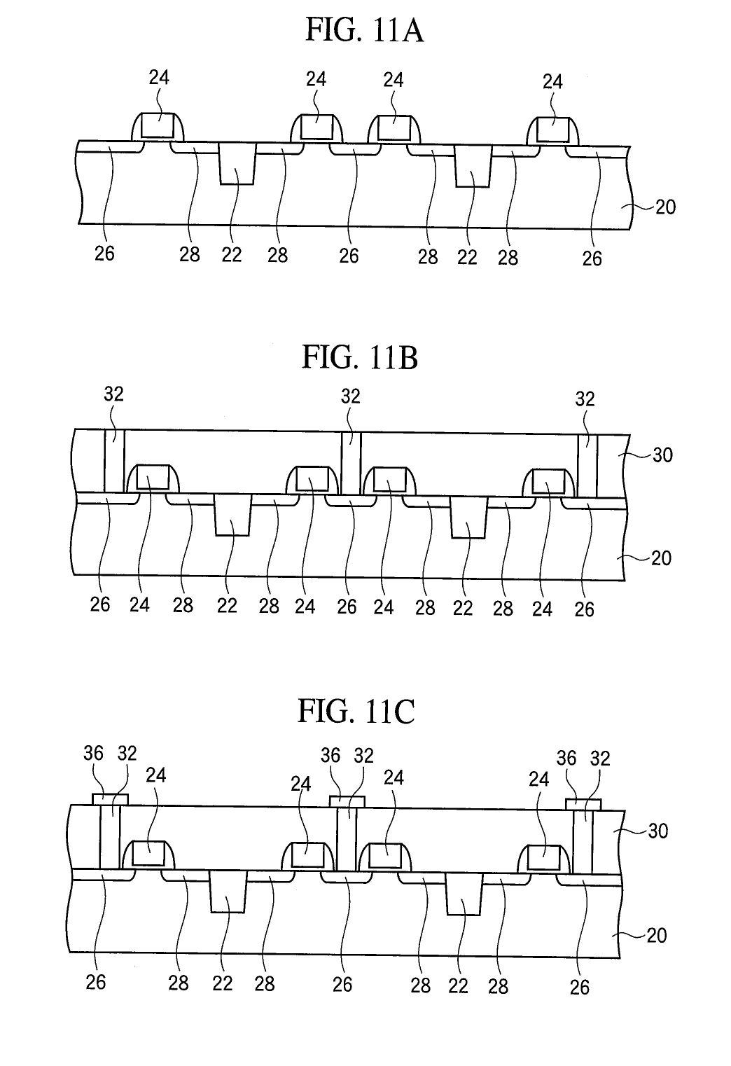

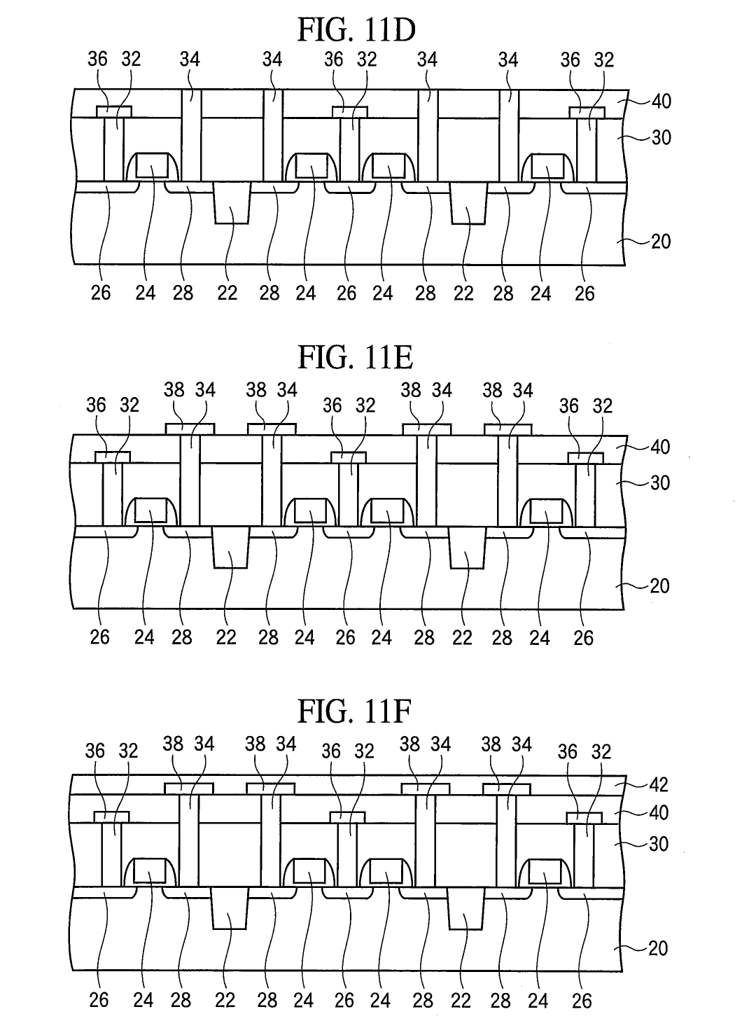

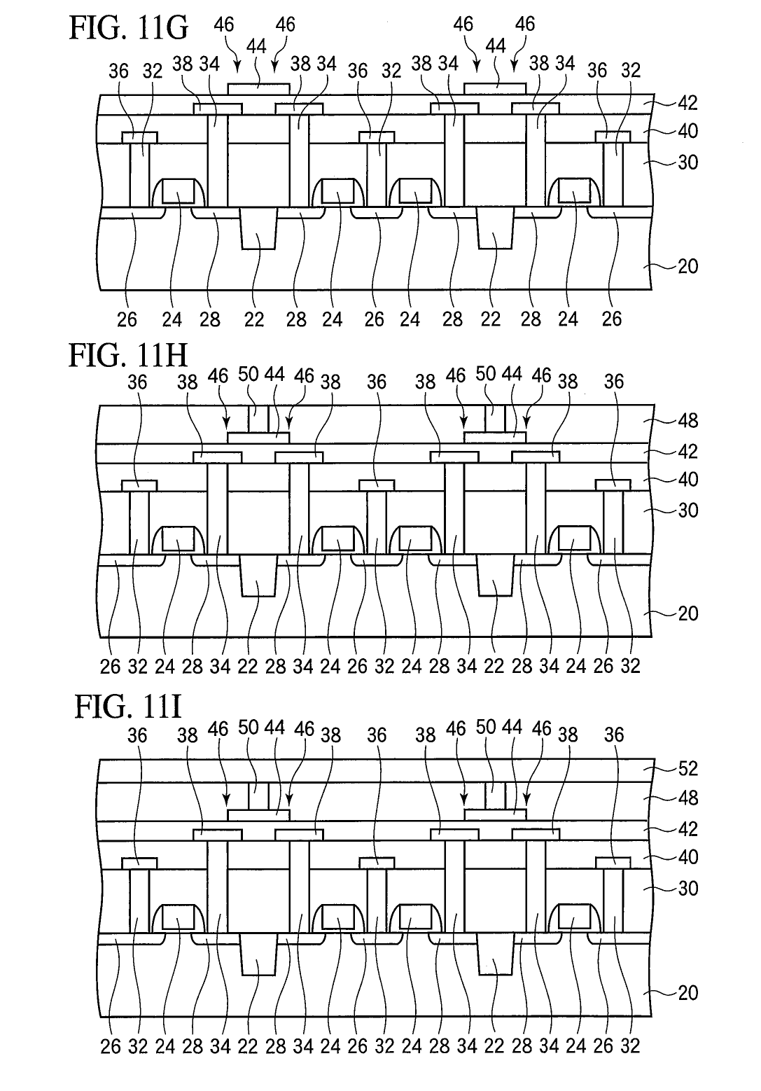

FIG. 1 is a graph showing the current-voltage characteristics of the resistance memory element using a bipolar resistance memory material. FIG. 2 is a graph showing the current-voltage characteristics of the resistance memory element using a unipolar resistance memory material. FIG. 3 is a graph showing the current-voltage characteristics explaining the forming processing of the resistance memory element. FIG. 4 is a graph showing the relationship between the voltage at which the forming takes place and the film thickness of the resistance memory layer. FIG. 5 is a graph showing the result of constant voltage TDDB measurement of the resistance memory element. FIG. 6 is a graph showing the current-voltage characteristics of the resistance memory element used in investigating the mechanism of the forming. FIG. 7 is a graph showing the current-voltage characteristics of each piece of the divided resistance memory element. FIG. 8 is a plan view showing the structure of the nonvolatile semiconductor memory device according to the present embodiment. FIG. 9 is a diagrammatic sectional view showing the structure of the nonvolatile semiconductor memory device according to the present embodiment. FIG. 10 is a circuit diagram showing the structure of the nonvolatile semiconductor memory device according to the present embodiment. FIGS. 11A-11I are sectional views showing the method of manufacturing the nonvolatile semiconductor memory device according to the present embodiment.

First, the basic operation of the resistance memory element will be explained with reference to FIGS. 1 and 2.

The resistance memory element includes the resistance memory material sandwiched between a pair of electrodes. Many of the resistance memory material are oxide materials containing transition metals, and the resistance memory material is divided largely in two, depending on differences in the electric characteristics.

One of them uses voltages of different polarities so as to change the resistance states between the high resistance state and the low resistance state and includes SrTiO₃ and SrZrO₃ doped with a trace of an impurity, such as chrome (Cr) or others, and Pr₁₋ₓCaₓMnO₃ and La₁₋ₓCaₓMnO₃, etc., which exhibit CMR (Colossal Magneto-Resistance). Such resistance memory material which requires voltages of different polarities so as to rewrite the resistance state will be hereinafter called the bipolar resistance memory material.

The other of them is materials which require voltages of the same polarity so as to change the resistance states between the high resistance state and the low resistance state and includes oxides, etc., containing a single transition metal, such as NiOₓ and TiOₓ. Such resistance memory materials which require voltages of the same polarity for rewriting the resistance states will be hereinafter called the unipolar resistance memory material.

FIG. 1 is a graph of the current-voltage characteristics of the resistance memory element using the bipolar resistance memory material and is disclosed in Reference 2. This graph is of the resistance memory element using Cr-doped SrZrO₃, which is the typical bipolar resistance memory material.

It is assumed that in the initial state, the resistance memory element is in the high resistance state.

As an applied voltage increases gradually from 0 V to negative voltages, the current flowing at this time changes along the curve “a” in the arrowed direction, and its absolute value gradually increases. When the applied negative voltage is further increased and exceed about −0.5 V, the resistance memory element switches from the high resistance state to the low resistance state. Accompanying this, the absolute value of the current abruptly increases, and the current-voltage characteristics transits from the point A to the point B. In the following explanation, the operation of changing the resistance memory element from the high resistance state to the low resistance state is called “set”.

As the negative voltage is gradually decreased from the state at the point B, the current changes along the curve “b” in the arrowed direction, and its absolute value gradually decreases. When the applied voltage returns to 0 V, the current also becomes 0 A.

As the applied voltage increases gradually from 0 V to positive voltages, the current value changes along the curve “c” in the arrowed direction, and its absolute values gradually increases. The applied positive voltage further increases and exceeds about 0.5 V, the resistance memory element switches from the low resistance state to the high resistance state. Accompanying this, the absolute value of the current abruptly decreases, and the current-voltage characteristics transit from the point C to the point D. In the following explanation, the operation of changing the resistance memory element from the low resistance state to the high resistance state is called “reset”.

As the positive voltage decreases from the state at the point D, the current changes along the curve “d” in the arrowed direction, and its absolute value gradually decreases. When the applied voltage returns to 0 V, the current also becomes 0 A.

The respective resistance states are stable in the range of about ±0.5 V and can be retained even when the electric power source is turned off. That is, in the high resistance state, when an applied voltage is lower than the absolute value of the voltage at the point A, the current-voltage characteristics changes linearly along the curves “a” and “d”, and the high resistance state is retained. Similarly, in the low resistance state, when an applied voltage is lower than the absolute value of the voltage at the point C, the current-voltage characteristics changes linearly along the curves “b” and “c”, and the low resistance state is retained.

As described above, for the resistance memory element using the bipolar resistance memory material, to change the resistance state between the high resistance state and the low resistance state, voltages of different polarities are applied.

FIG. 2 is a graph of the current-voltage characteristics of the resistance memory element using the unipolar resistance memory material. This graph is of the resistance memory element using TiOₓ, which is the typical unipolar resistance memory material.

It is assumed that in the initial state, the resistance memory element is in the high resistance state.

As an applied voltage is increased gradually from 0 V, the current increases along the curve “a” in the arrowed direction, and its absolute value gradually increases. When the applied voltage gradually increases and exceeds about 1.3 V, the resistance memory element is switched from the high resistance state to the low resistance state (set). Accompanying this, the absolute value of the current abruptly increases, and the current-voltage characteristics transit from the point A to the point B. In FIG. 2, the current value at the point B is constantly about 20 mA because of the current limiter for preventing the element from breaking due to abrupt current increases.

As the voltage decreases gradually from the state at the point B, the current changes along the curve “b” in the arrowed direction, and its absolute value gradually decreases. When the applied voltage returns to 0 V, the current also becomes 0 A.

As the applied voltage again increases gradually from 0 V, the current changes along the curve “c” in the arrowed direction, and its absolute value gradually increases. When the applied positive voltage further increases and exceeds about 1.2 V, the resistance memory element is switched from the low resistance state to the high resistance state (reset). Accompanying this, the absolute value of the current abruptly decreases, and the current-voltage characteristics transits from the point C to the point D.

As the voltage is decreased gradually from the point D, the current changes in the arrowed direction along the curve “d”, and the absolute value is gradually decreased. When the applied voltage returns to 0 V, the current also becomes 0 A.

The respective resistance states are stable not more than about 1.0 V and are retained when the electric power is turned off. That is, in the high resistance state, when the applied voltage is below the voltage at the point A, the current-voltage characteristics linearly change along the curve “a”, and the high resistance state is retained. Similarly, in the low resistance state, when the applied voltage is below the voltage at the point C, the current-voltage characteristics change along the curve “c”, and the low resistance state is retained.

As described above, in the resistance memory element using the unipolar resistance memory material, to change the resistance state between the high resistance state and the low resistance state, voltages of the same polarity are applied.

The resistance memory element formed of the above-described resistance memory material cannot have the characteristics shown in FIGS. 1 and 2 in the initial state immediately after the element formation. To make the resistance memory material reversibly changeable between the high resistance state and the low resistance state, the processing called “forming” is necessary.

FIG. 3 shows the current-voltage characteristics explaining the forming process of the resistance memory element using the same unipolar resistance memory material as in FIG. 2.

In the initial state immediately after the element has been formed, as shown in FIG. 3, the element is highly resistive and has a breakdown voltage of about 8 V which is very high. This breakdown voltage is very high in comparison with voltages necessary for the setting and resetting. In the initial state, changes of the resistance state, such as the setting and resetting, do not take place.

When a voltage higher than the breakdown voltage is applied in the initial state, as shown in FIG. 3, the value of the current flowing through the element abruptly increases, that is, the forming of the resistance memory element is made. Such forming is made, whereby the resistance memory element exhibits the current-voltage characteristics shown in FIG. 2 and can switch reversibly between the low resistance state and the high resistance state. Once subjected to the forming, the resistance memory element does not return to the initial state before the forming.

The resistance memory element in the initial state before subjected to the forming has a high resistance value, and this high resistance state might be misunderstood to be the high resistance state after the forming. In the specification of the present application, the high resistance state means the high resistance state of the resistance memory element after subjected to the forming, the low resistance state means the low resistance state of the resistance memory element after subjected to the forming, and the initial state is the state of the resistance memory element before subjected to the forming.

Next, the result of the mechanism of the forming the inventor of the present application investigated will be explained with reference to FIGS. 4 to 7. The sample used in the investigation was a resistance memory element including a lower electrode of a 150 nm-thickness Pt, a resistance memory layer of TiOₓ and an upper electrode of a 100 nm-thickness Pt.

FIG. 4 is a graph of the relationship between the voltage at which the forming takes place and the film thickness of the resistance memory layer. As shown in FIG. 4, the voltage at which the forming takes place (forming voltage) increases as the film thickness of the resistance memory layer increases. The measured points can be approximated linear, and the regression straight line passes the origin. This means that the voltage at which the forming takes place becomes zero at the limit. That is, the phenomenon of the forming will not be a phenomenon taking place at the interface between the electrode and the resistance memory layer but will be a phenomenon which takes place thickness-wise in the resistance memory layer.

FIG. 5 is a graph showing the result of the constant voltage TDDB (time-dependent dielectric breakdown) measurement of the sample before the forming processing. The measurement was made at room temperature. The applied voltage was 7 V, and the film thickness of the resistance memory layer was 30 nm. As shown in FIG. 5, after about 500 seconds have passed, the current value abruptly increases, and it is found that the dielectric breakdown has taken place. I-V measurement of the resistance memory element after the dielectric breakdown has taken place was measured. The RRAM characteristics shown in FIG. 6 were confirmed, and it was confirmed that the sample has been subjected to the forming processing.

In consideration of the results of FIGS. 4 to 6, the phenomenon of the forming is equivalent to the dielectric breakdown, and the dielectric breakdown will form a property changed region which is to be the current path.

Next, it will be explained that the RRAM characteristics as shown in FIG. 6 is caused by the property changed region.

First, a resistance memory element having a 500 μm-diameter of the upper electrode is formed and was subjected to the forming processing. Then, the resistance memory element was switched from the high resistance state to the low resistance state. The current-voltage characteristics of the resistance memory element at this time are indicated by the o marks in FIG. 7.

Then, this resistance memory element was cut in two pieces, and the current-voltage characteristics were again measured on the respective cut pieces. The current-voltage characteristics of the respective pieces are shown in FIG. 7 respectively by the dotted line and the solid line.

The result was that one piece (indicated by the dotted line) was in the low resistance state and well agreed with the measured data of the resistance memory element in the low resistance state set after the electrodes were cut. In contrast to this, the other piece (indicated by the solid line) remained in the state before the forming processing. Based on them, it is found that the current path generated by the forming is contained only in said one piece, and said one piece alone memorizes the resistance state before the electrodes were cut. The other piece does not contribute at all to memorizing the resistance state.

Based on the above-described result, the property changed region formed by the forming will be in a very narrow local region. In combination with the result of FIG. 4, this property changed region will be like a filament extended in the direction of film thickness of the resistance memory layer.

The RRAM characteristics of the resistance memory element will be generated in the filament shaped property changed region generated by the forming. Accordingly, the electric response changes before and after the switching are not substantially dependent on the electrode areas, as are in FeRAM and MRAM, and this permits the areas of the electrodes to be drastically reduced. The upper electrode and the lower electrode, which sandwich the resistance memory layer, may not be provided essentially 1:1. For one lower electrode as the common electrode, a plurality of discrete upper electrodes is provided, or for a plurality of discrete lower electrodes, one upper electrode as the common electrode may be provided.

The mechanism for the filament shaped property changed region providing the RRAM characteristics is not clear, but the inventor of the present application presumes as follows.

A resistance memory element is formed and is subjected to the forming processing to generate the dielectric breakdown, and then the filament shaped property changed region is formed in the resistance memory layer. A current path is formed in this property changed region. This state is the low resistance state of the resistance memory element.

When a voltage is applied to the resistance memory element in the low resistance state, a current flows via the current path. When the value of the current becomes large, an oxidation reaction similar to the anodic oxidation takes place and acts to restore the property changed region. Thus, the property-changed region is decreased, which makes the current path narrow, or oxidation advances around a vicinity of the interface of the pass with the electrode, which blocks the current path, and a high resistance state is generated. This state is the high resistance state of the resistance memory element.

When a voltage of not less than the prescribed value to the resistance memory element in the high resistance state, dielectric breakdown takes place in the oxidized region blocking the current path, and the current path is again formed. Thus, the resistance memory element returns to the low resistance state.

Next, the nonvolatile semiconductor memory device and the method of manufacturing the same according to the present embodiment will be explained with reference to FIGS. 8 to 11I.

As shown in FIGS. 8 and 9, a device isolation film 22 for defining device regions is formed in a silicon substrate 20. In the device regions of the silicon substrate 20, cell select transistors each including a gate electrode 24, and source/drain regions 26, 28 are formed.

The gate electrodes 24 function also as word lines WL commonly connecting the gate electrodes 24 of the cell select transistors arranged column-wise (vertically in the drawing).

Over the silicon substrate 20 with the cell select transistors formed on, an inter-layer insulating film 30 with contact plugs 32 electrically connected to the source/drain regions 26 buried in is formed. Over the inter-layer insulating film 30, source lines 36 electrically connected to the source/drain regions 26 via the contact plugs 32 are formed.

Over the inter-layer insulating film 30 with the source lines 36 formed on, an inter-layer insulating film 40 with contact plugs 34 electrically connected to the source/drain regions 28 buried in is formed.

Over the inter-layer insulating film 40, lower electrodes 38 electrically connected to the source/drain regions 28 via the contact plugs 34 are formed. The lower electrodes 38 are formed one for each contact plugs 34. Over the inter-layer insulating film 40 with the lower electrodes 38 formed on, a resistance memory layer 42 is formed. Over the resistance memory layer 42, upper electrodes 44 are formed. Each upper electrode 44 is formed overlapping the lower electrodes 38 of each couple of the lower electrodes 38 adjacent row-wise (transversely in the drawing) with the device isolation region therebetween. Thus, over the inter-layer insulating film 40, resistance memory elements 46 each including the lower electrode 38, the resistance memory layer 42 and the upper electrode 44 are formed. Each upper electrode 44 is common between the two resistance memory elements 46 adjacent row-wise with the device isolation region therebetween.

Over the resistance memory elements 46, an inter-layer insulating film 48 is formed. In the inter-layer insulating film 38, contact plugs 50 electrically connected to the upper electrodes 44 of the resistance memory elements 46 are buried.

Over the inter-layer insulating film 48 with the contact plugs 50 buried in, bit lines 52 connected to the upper electrodes 44 of the resistance memory elements 46 via the contact plugs 50 and extended row-wise are formed.

As described above, the nonvolatile semiconductor memory device according to the present embodiment is characterized mainly in that the upper electrodes 44 are common between the resistance memory elements 46 adjacent row-wise. The electric characteristics of the resistance memory elements 46 are set by the filament shaped property changed region to be formed in the resistance memory layer 42. Accordingly, when two lower electrodes 38 are provided for one upper electrode 44, the filament shaped property changed regions are formed respectively between the upper electrode and the two lower electrodes 38 to be memory regions, and two resistance memory elements 46 can function.

That is, the upper electrodes 44 are allowed to have a larger area than the lower electrodes 38 without affecting the unit memory cell. This very advantageously provides a merit that when the contact plugs 50 are connected to the upper electrodes, the alignment margin can be mitigated, and the other merits.

The filament shaped property changed regions formed in the resistance memory layer 42 are much small, which permits the lower electrodes 38 to be reduced to the minimum processing size of the design rules. Thus, the devices can be downsized.

It is necessary that the two lower electrodes 38 for one upper electrode 44 is arranged at a gap which does not cause the forming in the resistance memory layer 42 between the lower electrodes 38 when the resistance memory elements 46 have the data rewritten. That is, the gap of the lower electrodes 38 is stipulated so that a voltage which causes the forming in the resistance memory layer 42 between the lower electrodes 38 becomes higher than a maximum voltage difference to be applied between the lower electrodes 38 when the data of the resistance memory elements 46 are rewritten.

When a maximum voltage difference to be applied between the lower electrodes 38 upon the data rewriting of the resistance memory element 46 is a writing voltage (set voltage) of the resistance memory element 46, in the resistance memory element 46 having, e.g., the characteristics shown in FIG. 6, the voltage for causing the forming is about 1.7 V. The film thickness of the resistance memory layer 42, with which the voltage for causing the forming is 1.7 V is computed from the graph of FIG. 4 to be about 9 nm. That is, when the gap of the lower electrodes 38 is ensured to be larger than 9 nm, the forming never take place in the resistance memory layer 42 between the lower electrodes 38 even when a voltage equivalent to the set voltage or the resetting voltage is applied between the lower electrodes 38.

It is effective to make the gap between the lower electrodes 38 larger than a distance equivalent to the film thickness of the resistance memory layer 42. Thus, the voltage for causing the forming in the resistance memory layer 42 between the lower electrodes 38 is higher than the voltage for causing the forming between the lower electrode 38 and the upper electrode 44, whereby the occurrence of the forming in the resistance memory layer 42 upon the data rewriting of the resistance memory elements 46 can be effective prevented.

It is preferable to set the gap between the lower electrodes 38 suitably depending on structures and constituent materials, methods for applying a voltage upon data rewriting, etc.

The memory cell 10 of the nonvolatile semiconductor memory device according to the present embodiment shown in FIGS. 8 and 9 includes a resistance memory element 12 and a cell select transistor 14 as shown in FIG. 10. The resistance memory element 12 has one terminal connected to a bit line BL and the other terminal connected to the drain terminal of the cell select transistor 14. The cell select transistor 14 has the source terminal connected to a source line SL and the gate terminal connected to a word line WL. Such memory cells 10 are formed column-wise (vertically in the drawing) and the row-wise (transversely in the drawing) adjacent to each other.

A plurality of word lines WL1, /WL1, WL2, /WL2, . . . are arranged column-wise and form signal lines common among the memory cells 10 arranged column wise. Source lines SL1, SL2, . . . are arranged column-wise and form signal lines common among the memory cells 10 arranged column-wise. The source lines SL are provided one for two word lines WL.

A plurality of bit lines BL1, BL2, BL3, BL4, are arranged row-wise (transversely in the drawing) and form signal lines common among the memory cells 10 arranged row-wise.

Then, the method of writing into the nonvolatile semiconductor memory device according to the present embodiment will be explained with reference to FIG. 10. It is assumed that the forming processing of the resistance memory elements has been finished.

First, the writing operation from the high resistance state to the low resistance state, i.e., the setting operation will be explained. The memory cell 10 to be rewritten is a memory cell 10 connected to the word line WL1 and the bit line BL1.

First, a prescribed voltage is applied to the word line WL1 to turn on the cell select transistor 14. The source line SL1 is connected to a reference potential, e.g., 0 V, which is the ground potential.

Next, the bias voltage which is equal to or a little higher than a voltage required to set the resistance memory element 12 is applied to the bit line BL1. For the resistance memory element having, e.g., the characteristics shown in FIG. 6, the bias voltage of, e.g., about 2 V is applied.

Thus, a current path to the source line SL1 via the bit line BL1, the resistance memory element 12 and the cell select transistor 14 is formed, and the applied bias voltage is divided to the resistance memory element 12 and the cell select transistor 14 corresponding to a resistance value R_{H} of the resistance memory element 12 and a channel resistance R_{CS} of the cell select transistor 14.

At this time, the resistance value R_{H} of the resistance memory element 12 is sufficiently larger than the channel resistance R_{CS} of the cell select transistor, and accordingly most of the bias voltage is applied to the resistance memory element 12. Thus, the resistance memory element 12 is changed form the high resistance state to the low resistance state.

Next, the bias voltage to be applied to the bit line BL1 is returned to zero, and then the voltage to be applied to the word line WL1 is turned off. The setting operation is completed.

Next, the rewriting operation from the low resistance state to the high resistance state, i.e., the resetting operation will be explained. The memory cell to be rewritten is a memory cell 10 connected to the word line WL1 and the bit line BL1.

First, a prescribed voltage is applied to the word line WL1 to turn on the cell select transistor 14. The source line SL is connected to a reference potential, e.g., 0 V, which is the ground potential.

Then, the bias voltage which is equal to or a little higher than a voltage required to reset the resistance memory element 12 is applied to the bit line BL1. For resistance memory element having, e.g., the characteristics shown in FIG. 6, a bias voltage of, e.g., about 1.2 V is applied.

Thus, a current path to the source line SL1 via the bit line BL1, the resistance memory element 12 and the cell select transistor 14 is formed, and the applied bias voltage is divided to the resistance memory element 12 and the cell select transistor 14 corresponding to a resistance value R_{L} of the resistance memory element 12 and a channel resistance R_{CS} of the cell select transistor 14.

At this time, the channel resistance R_{CS} of the cell select transistor 14 is sufficiently smaller than the resistance value R_{L} of the resistance memory element 12, accordingly most of the applied bias voltage is applied to the resistance memory element 12. Thus, the resistance memory element 12 is changed form the low resistance state to the high resistance state.

In the resetting process, the instant the resistance memory element 12 has changed to the high resistance state, almost all the bias voltage is divided to the resistance memory element 12, and accordingly it is necessary to prevent the resistance memory element from being set again by this bias voltage. To this end, the bias voltage to be applied to the bit line BL must be smaller than a voltage necessary for the setting.

That is, in the resetting process, the gate voltages of the cell select transistor 14 and the resistance memory element 12 are adjusted so that the channel resistance R_{CS} of the cell select transistor 14 is made sufficiently smaller than the resistance value R_{L} of the resistance memory element 12 while the bias voltage to be applied to the bit line BL is set not less than a voltage necessary for the resetting and less than a voltage necessary for the setting.

Then, the bias voltage to be applied to the bit line BL1 is returned to zero, and then the voltage to be applied to the word line WL is turned off. The resetting operation is completed.

In the nonvolatile semiconductor memory device according to the present embodiment, as shown in FIG. 10, the word lines WL and the source lines SL are arranged column-wise, and the memory cells 10 connected to one word line (e.g., WL1) are connected to the same source line SL (e.g., SL1). Accordingly, a plurality of the bit lines BL (e.g., BL1-BL4) are simultaneously driven in the above-described resetting operation, and a plurality of the memory cells 10 connected to the selected word line (e.g., WL1) can be reset at once.

Next, the method of reading the nonvolatile semiconductor memory device according to the present embodiment shown in FIG. 10 will be explained. The memory cell 10 to be read is a memory cell 10 connected to the word line WL1 and the bit line BL1.

First, a prescribed voltage is applied to the word line WL1 to turn on the cell select transistor 14. The source line SL1 is connected to a reference potential, e.g., 0 V, which is the ground potential.

Then, a prescribed bias voltage is applied to the bit line BL1. This bias voltage is set not to set or rest the resistance memory element 12 in any resistance state.

When such bias voltage is applied to the bit line BL1, current corresponding to a resistance value of the resistance memory element 12 flows in the bit line BL1. Accordingly, the value of the current flowing in the bit line BL1 is detected, whereby the resistance state of the resistance memory element 12 can be read.

Next, the method of manufacturing the nonvolatile semiconductor memory device according to the present embodiment will be explained with reference to FIGS. 11A to 11I.

First, in the silicon substrate 20, the device isolation film 22 for defining device regions is formed by, e.g., STI (Shallow Trench Isolation) method.

Next, in the device regions of the silicon substrate 20, the cell select transistors each including the gate electrode 24 and the source/drain regions 26, 28 are formed by the usual MOS transistor manufacturing method (FIG. 11A).

Next, over the silicon substrate 10 with the cell select transistors formed on, a silicon oxide film is deposited by, e.g., CVD (chemical vapor deposition) method to form the inter-layer insulating film 30 of the silicon oxide film.

Next, by photolithography and dry etching, contact holes down to the source/drain regions 26 are formed in the inter-layer insulating film 30.

Next a barrier metal and a tungsten film are deposited by, e.g., CVD method, and then these conductive films are etched back to form in the contact holes the contact plugs 32 electrically connected to the source/drain regions 26 (FIG. 11B).

Next, over the inter-layer insulating film 30 with the contact plugs 32 buried in, a platinum (Pt) film is deposited by, e.g., CVD method.

Next, by photolithography and dry etching, the platinum film is patterned to form the source lines 36 electrically connected to the source/drain regions 26 via the contact plugs 32 (FIG. 11C).

Next, over the inter-layer insulating film 30 with the source lines 36 formed on, a silicon oxide film is deposited by, e.g., CVD method to form the inter-layer insulating film 40 of the silicon oxide film.

Then, by photolithography and dry etching, contact holes down to the source/drain regions 28 are formed in the inter-layer insulating films 40, 30.

Then, the barrier metal and the tungsten film are deposited by, e.g., CVD method, and these conductive films are etched back to form in the contact holes the contact plugs 34 electrically connected to the source/drain regions 28 (FIG. 11D).

Next, over the inter-layer insulating film 40 with the contact plugs 34 buried in, a platinum film is deposited by, e.g., CVD method.

Then, by photolithography and dry etching, the platinum film is patterned to form the lower electrodes 38 electrically connected to the source/drain regions 28 via the contact plugs 34 (FIG. 11E). The lower electrodes 38 are provided for the respective contact plugs 34.

Next, over the inter-layer insulating film 40 with the lower electrodes 38 formed on, a 50 nm-thickness TiOₓ film, for example, is deposited by laser ablation method, sol-gel method, sputtering method, MOCVD method or other methods to form the resistance memory layer 42 of the TiOₓ film (FIG. 11F).

Then, over the resistance memory layer 42, a platinum film is deposited by, e.g., CVD method.

Next, by photolithography and dry etching, the platinum film is patterned to form the upper electrodes 44 of the platinum film (FIG. 11G).

Each upper electrode 55 is formed, overlapping a couple of the lower electrodes 38 adjacent to each other with the device isolation region therebetween in the extending direction of the bit lines. Thus, a couple of the resistance memory elements 46 including the upper electrode 44 in common is formed adjacent to each other with the device isolation region therebetween in the extending direction of the bit lines.

Then, a silicon oxide film is deposited by, e.g., CVD method, and then the surface of the silicon oxide film is planarized by, e.g., CMP (chemical mechanical polishing) method to form the inter-layer insulating film 48 of the silicon oxide film.

Next, by photolithography and dry etching, contact holes down to the upper electrodes 44 of the resistance memory elements 46 are formed in the inter-layer insulating film 48.

Next, a barrier metal and a tungsten film are deposited by, e.g., CVD method, and these conductive films are etched back to form in the contact holes the contact plugs 50 electrically connected to the upper electrodes 44 of the resistance memory elements 46 (FIG. 11H).

Then, over the inter-layer insulating film 48 with the contact plugs 50 buried in, a conductive film is deposited, and then the conductive film is patterned by photolithography and dry etching to form the bit lines 52 connected to the resistance memory elements 46 via the contact plugs 50 (FIG. 11I).

Then, upper-level interconnection layers are further formed as required, and the nonvolatile semiconductor memory device is completed.

As described above, according to the present embodiment, a plurality of the resistance memory elements commonly include an upper electrode, which allows the upper electrode to be large without influencing the area of the unit memory cell. Thus, the alignment margin of the interconnections and the contact plugs connected to the upper electrodes can be improved, and the manufacturing process can be simplified. The lower electrodes may be reduced to a minimum processing size of the design rules, which permits the devices to be downsized.

### A Second Embodiment

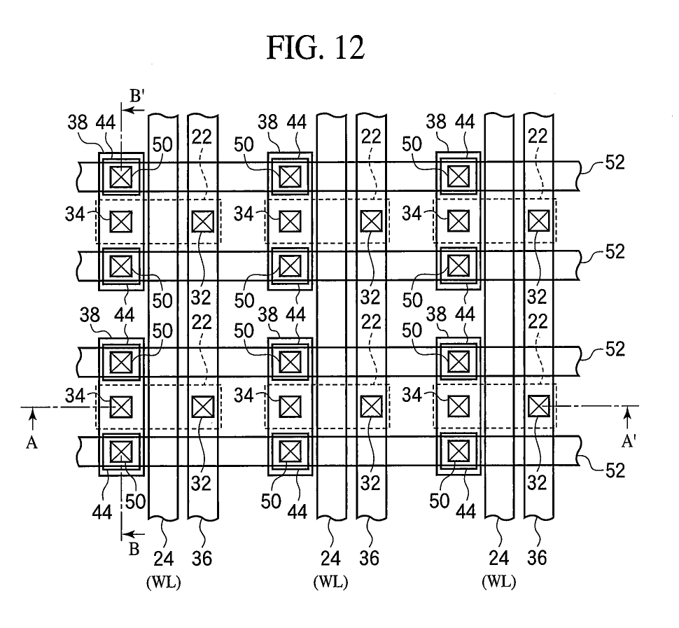

The nonvolatile semiconductor memory device and method of writing into the same according to a second embodiment of the present invention will be explained with reference to FIGS. 12 to 15G.

The same members of the present embodiment as those of the nonvolatile semiconductor memory device and the method of writing into the same according to the first embodiment shown in FIGS. 1 to 11I are represented by the same reference numbers not to repeat or to simplify their explanation.

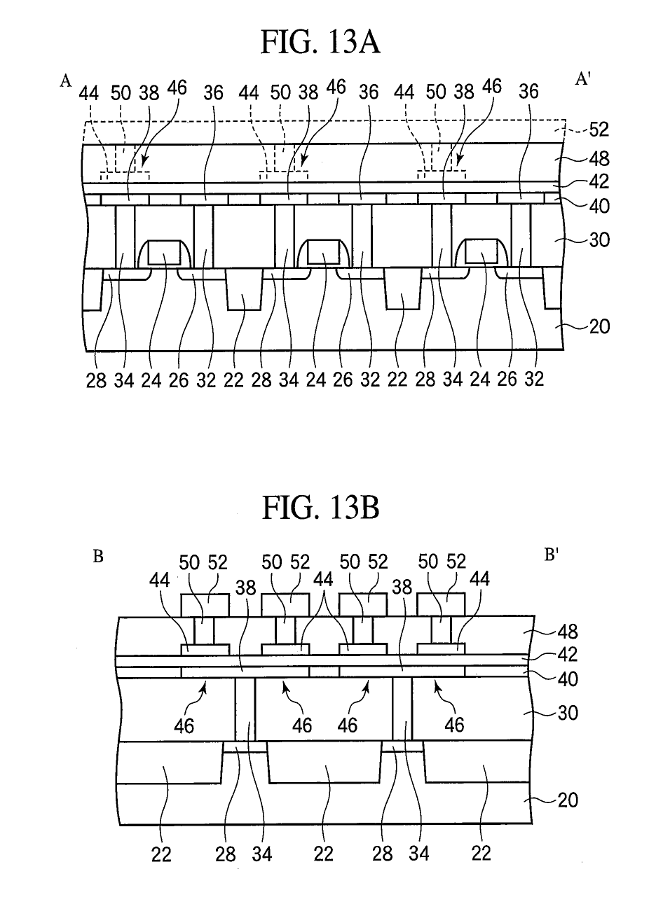

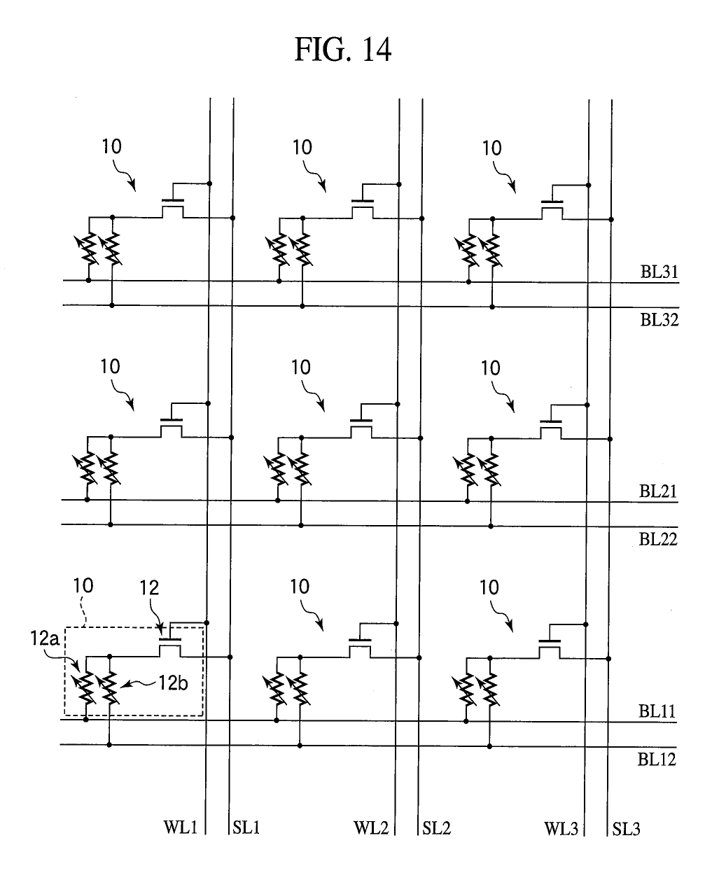

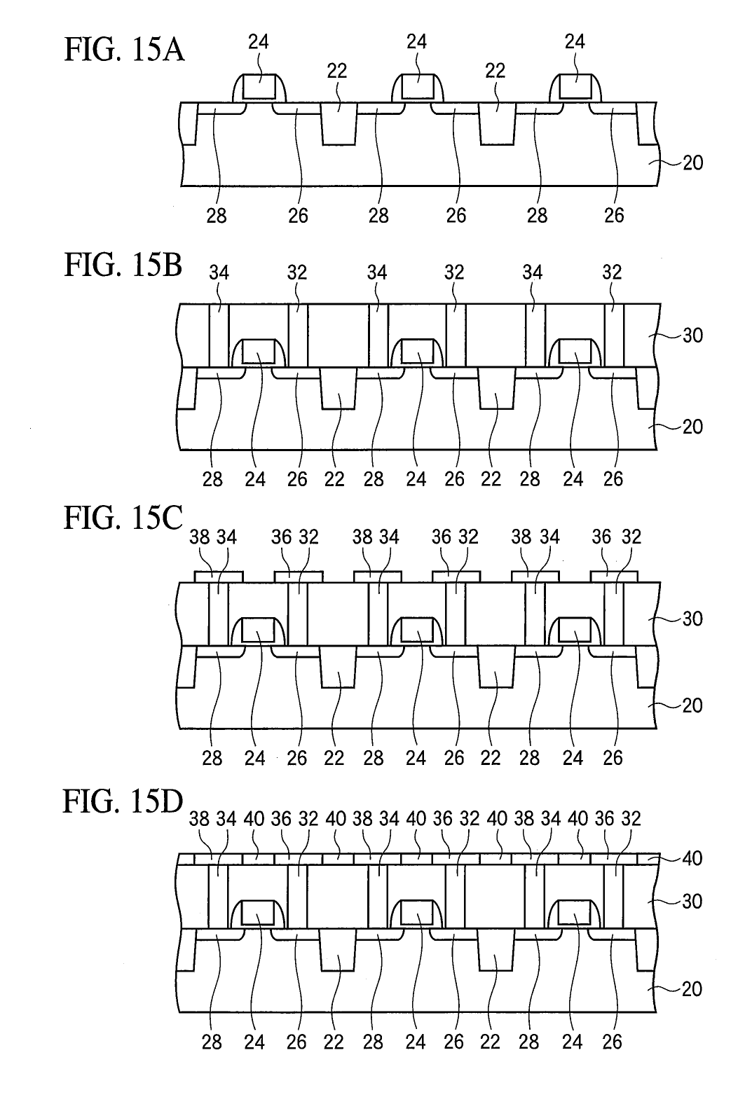

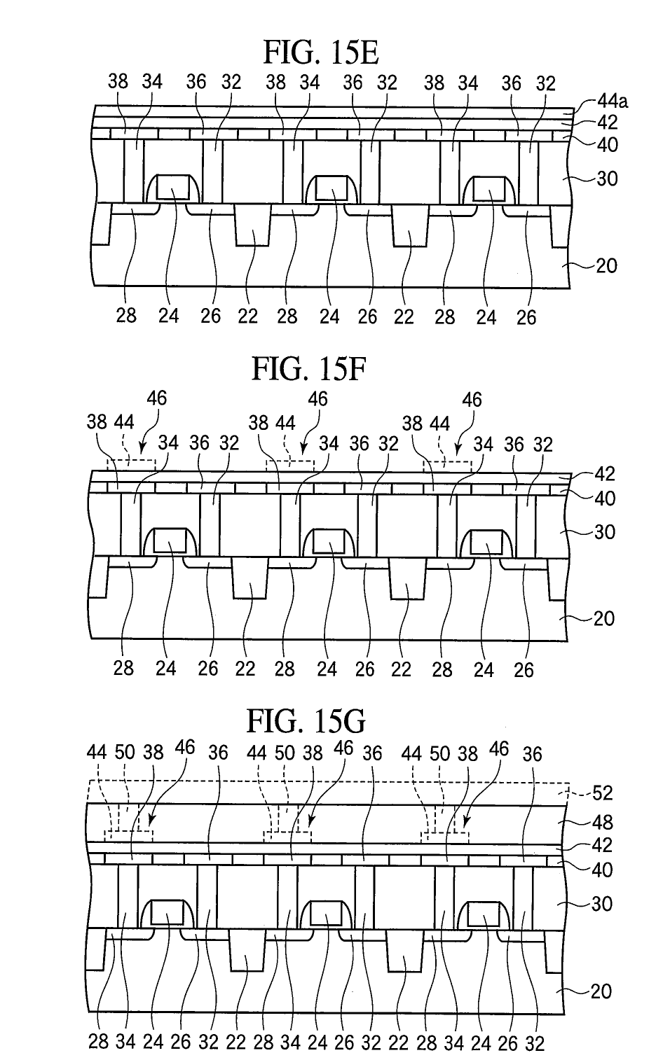

FIG. 12 is a plan view showing the structure of the nonvolatile semiconductor memory device according to the present embodiment. FIGS. 13A and 13B are diagrammatic sectional views showing the structure of the nonvolatile semiconductor memory device according to the present embodiment. FIG. 14 is a circuit diagram showing the structure of the nonvolatile semiconductor memory device according to the present embodiment. FIGS. 15A-15G are sectional views showing the method of manufacturing the nonvolatile semiconductor memory device according to the present embodiment.

First, the structure of the nonvolatile semiconductor memory device according to the present embodiment will be explained with reference to FIGS. 12, 13A and 13B. FIG. 13A is the sectional view along the A-A′ line in FIG. 12, and FIG. 13B is the sectional view along the B-B′ line in FIG. 12.

As shown in FIGS. 12, 13A and 13B, in the silicon substrate 20, the device isolation film 22 for defining device regions is formed. In the device regions of the silicon substrate 20, the cell select transistors each including the gate electrode 24 and the source/drain regions 26, 28 are formed.

As shown in FIG. 8, the gate electrodes 24 function as the word lines WL commonly connecting the gate electrodes 24 of the cell select transistors arranged column-wise (vertically in the drawing).

Over the silicon substrate 20 with the cell select transistors formed on, an inter-layer insulating film 30 with contact plugs 32 electrically connected to the source/drain regions 26 and contact plugs 34 electrically connected to the source/drain regions 28 buried in is formed. Over the inter-layer insulating film 30, source lines 36 electrically connected to the source/drain regions 26 via the contact plugs 32, and lower electrodes 38 electrically connected to the source/drain regions 28 via the contact plugs 34 are formed. The lower electrodes 38 has a rectangular shape elongated column-wise and are connected to the contact plugs 34 at the centers thereof (see FIG. 12).

Over the inter-layer insulating film 30 in the region except the regions where the source lines 36 and the lower electrodes 38 are formed, an inter-layer insulating film 40 is formed. Thus, the surfaces of the source lines 36, the lower electrodes 38 and the inter-layer insulating film 40 are planarized.

Over the source lines 36, the lower electrodes 38 and the inter-layer insulating film 40, a resistance memory layer 42 is formed. Over the resistance memory layer 42, upper electrodes 44 are formed. The upper electrodes are formed two above respective one lower electrode 38. Thus, two resistance memory elements 46 including one lower electrode 38 in common are formed respectively in the region where the lower electrode 38 is formed.

Over the resistance memory elements 46, an inter-layer insulating film 48 is formed. In the inter-layer insulating film 48, contact plugs 50 electrically connected to the upper electrodes 44 of the resistance memory elements 46 are buried.

Over the inter-layer insulating film 48 with the contact plugs 50 buried in, bit lines 52 connected to the upper electrodes 44 of the resistance memory elements 46 via the contact plugs 50 and extended row-wise are formed.

As described above, the nonvolatile semiconductor memory device according to the present embodiment is characterized mainly in that the lower electrodes 38 of the resistance memory elements 46 adjacent to each other column-wise commonly included. The two resistance memory elements including the lower electrode 38 in common are connected to one select transistor.

The electric characteristics of the resistance memory elements 46 are set by the filament shaped property changed region formed in the resistance memory layer 42. When two upper electrodes 44 are provided for one lower electrode 38, the filament shaped property changed regions are formed respectively between the upper electrode and the two lower electrodes 38 to be memory regions, and can function as two resistance memory elements 46. Thus, the elements can be downsized. In the nonvolatile semiconductor memory device according to the present embodiment, one cell select transistor may be provided for two resistance memory elements 46, which further improve the integration of the elements.

FIG. 14 is the circuit diagram of the nonvolatile semiconductor memory device according to the present embodiment shown in FIGS. 4, 5A and 5B. As shown in FIG. 14, one memory cell 10 includes one cell select transistor 14 and two resistance memory elements 12a, 12b. The cell select transistor 14 has the source terminal connected to the source line SL (SL1) and the gate terminal connected to the word line WL (WL1). One terminals of the resistance memory elements 12a, 12b are connected to the drain terminal of the cell select transistor 14. The other terminals of the resistance memory elements 12a, 12b are connected respectively to different bit lines BL (BL11, BL12). Such memory cells 10 are formed adjacent to each other column-wise (vertically in the drawing) and row-wise (transversely in the drawing).

A plurality of word lines WL1, WL2, WL3, . . . are arranged column-wise, forming common signal lines for the memory cells 10 arranged column-wise. The source lines SL1, SL2, . . . are arranged column-wise, forming common signal lines for the memory cells 10 arranged column-wise.

A plurality of bit lines BL11, BL12, BL21, BL22, BL31, BL32, . . . are arranged row-wise (transversely in the drawing), forming common signal lines for the memory cells arranged row-wise.

Next, the method of writing into the nonvolatile semiconductor memory device according to the present embodiment will be explained with reference to FIG. 14. It is assumed that the forming processing of the resistance memory elements has been finished.

In the method of writing into the nonvolatile semiconductor memory device according to the present embodiment, first, a sector of the memory cells, which contain a memory cell 10 to be rewritten is collectively reset. Then, the memory cell 10 is rewritten.

First, the collective reset of the sector will be explained. In the following explanation, the memory cells connected to the word lines WL1-WL3, the bit lines BL11, BL12 and the source lines SL1-SL3 are collectively reset.

First, a prescribed voltage is applied to the word lines WL1, WL2, WL3 to turn on the cell select transistors 14. The source lines SL1, SL2, SL3 are connected to a reference potential, e.g., 0 V, which is the ground potential.

Next, a bias voltage (reset voltage V_{RESET}) which is equal to or a little higher than a voltage necessary to reset the resistance memory elements 12 is applied. For the resistance memory element having the characteristics shown, e.g., in FIG. 6, a bias voltage of, e.g., about 1 V is applied. The bit lines BL21, BL22, BL31, BL32 are floating.

Thus, the reset voltage V_{RESET} is applied to the respective resistance memory elements 12, and the resistance memory elements having the high resistance state are reset to have the low resistance state. The resistance memory elements 12 having the low resistance state are retained in the low resistance state.

Thus, the collective resetting of the memory cells 10 connected to the bit lines BL11, BL12 is completed.

Next, the method of writing into the memory cells 10 will be explained. The writing is made in the memory cell 10 connected to the word line WL1, the bit lines BL11, BL12 and the source line SL1.

When the writing is made in the memory cell 10, voltages to be applied to the respective signal lines are selected out of (1) to (4) described below in accordance with combination of information to be written in the resistance memory elements 12a, 12b.

(1) To Write the High Resistance State in Both the Resistance Memory Elements 12a, 12b

When the high resistance state is written in the resistance memory elements 12a, 12b, no special processing is required. After the collective setting has been completed, the resistance memory elements 12a, 12b have the high resistance state. Accordingly, when the high resistance state is written in the resistance memory elements 12a, 12b, only the processing of the collective setting may be made.

(2) To Write the High Resistance State in the Resistance Memory Element 12a and Low Resistance State in the Resistance Memory Element 12b

A prescribed voltage is applied to the word line WL1 to turn on the cell select transistor 14, and the source line SL1 is connected to a reference voltage, e.g., 0 V, which is the ground potential.

Next, a voltage of V_{SET}−ΔV_{SET} is applied to the bit line BL11, and a voltage of V_{SET}+ΔV_{SET} is applied to the bit line BL12. A voltage V_{SET} is a voltage necessary to set the resistance memory elements 12 (set voltage), and a voltage ΔV_{SET} is a voltage which satisfies 2ΔV_{SET}<V_{RESET}.

Thus, to the resistance memory element 12b, the voltage of V_{SET}+ΔV_{SET}, which is higher than the set voltage, is applied, and the resistance memory element 12b is switched from the high resistance state to be set in the low resistance state. On the other hand, a voltage to be applied to the resistance memory element 12a is the voltage (V_{SET}−ΔV_{SET}), and the resistance memory element 12a is retained in the high resistance state. The voltage between the bit line BL11 and the bit line BL12 is 2ΔV_{SET}, which is lower than the reset voltage V_{RESET}, and the adjacent memory cells are not disturbed. Thus, the writing of the high resistance state in the resistance memory element 12a and the writing of the low resistance state in the resistance memory element 12b are completed.

(3) To Write the Low Resistance State in the Resistance Memory Element 12a and the High Resistance State in the Resistance Memory Element 12b

The prescribed voltage is applied to the word line WL1 to turn on the cell select transistor 14, and the source line SL1 is connected to the reference potential, e.g., 0 V, which is the ground potential.

Next, to the bit line BL11, the voltage of V_{SET}+ΔV_{SET} is applied, and the voltage of V_{SET}−ΔV_{SET} is applied to the bit line BL12.

Thus, to the resistance memory element 12a, the voltage of V_{SET}+ΔV_{SET}, which is higher than the set voltage, is applied, and the resistance memory element 12a is switched from the high resistance state to be set in the low resistance state. On the other hand, the voltage to be applied to the resistance memory element 12b is the voltage (V_{SET}−ΔV_{SET}), which is lower than the set voltage, and the resistance memory element 12b is retained in the high resistance state. The voltage between the bit line BL11 and the bit line BL12 is 2ΔV_{SET}, which is lower than the reset voltage V_{RESET}, and the adjacent memory cells are not disturbed. Thus, the writing of the low resistance state in the resistance memory element 12a and the writing of the high resistance state in the resistance memory element 12b are completed.

(4) To Write the Low Resistance State in Both the Resistance Memory Elements 12a, 12b

To the word line WL1, the prescribed voltage is applied to the cell select transistor 14 is turned on, and the source line SL1 is connected to the reference potential, e.g., 0 V, which is the ground potential.

Next, the voltage of V_{SET}+ΔV_{SET} is applied to the bit lines BL11, BL12.

Thus, the voltage of V_{SET}+ΔV_{SET}, which is higher than the set voltage, is applied to the resistance memory elements 12a, 12b, and the resistance memory elements 12a, 12b are switched from the high resistance state to be set in the low resistance state. The voltage between the bit line BL11 and the bit line BL12 is 0 V, and the adjacent memory cells are not disturbed. Thus, the writing of the low resistance state in the resistance memory elements 12a, 12b is completed.

Next, the method of reading the nonvolatile semiconductor memory device according to the present embodiment shown in FIG. 14 will be explained. The resistance memory cell to be read is a memory cell 10 connected to the word line WL1 and the bit line BL11.

First, a prescribed voltage is applied to the word line WL1 to turn on the cell select transistor 14. The source line SL1 is connected to a reference potential, e.g., 0 V, which is the ground potential. The word lines WL2, WL3, . . . , the bit lines BL21, BL22, BL31, BL32, . . . and the source lines SL2, SL3, . . . are floating.

Next, to the bit lines BL11, BL12, prescribed bias voltages which are equal to each other are applied.

These bias voltages are set at a value lower than the reset voltage V_{RESET} so that neither the setting nor the resetting takes place with the applied voltages when the resistance memory elements 12a, 12b are in any resistance state.

When such bias voltages are applied to the bit lines BL11, BL12, a current corresponding to a resistance value of the resistance memory element 12a flows in the bit line BL11. In the bit line BL12, a current corresponding to a resistance value of the resistance memory element 12b flows. Accordingly, values of these currents are detected, whereby resistances states of the resistance memory elements 12a, 12b can be read.

Next, the method of manufacturing the nonvolatile semiconductor memory device according to the present embodiment will be explained with reference to FIGS. 15A to 15G.

First, in the silicon substrate 20, the device isolation film 22 for defining device regions is formed by, STI (Shallow Trench Isolation) method.

Next, in the device regions of the silicon substrate 20, the cell select transistors each including the gate electrode 24, and the source/drain regions 26, 28 are formed in the same way as in the usual MOS transistor manufacturing method (FIG. 15A).

Next, over the silicon substrate 20 with the cell select transistors formed on, a silicon oxide film is deposited by, e.g., CVD method to form the inter-layer insulating film 30 of the silicon oxide film.

Next, by photolithography and dry etching, contact holes down to the source/drain regions 26, 28 are formed in the inter-layer insulating film 30.

Next, a barrier metal and a tungsten film are deposited by, e.g., CVD method, and these conductive films are etched back to form, in the contact holes, the contact plugs 32 electrically connected to the source/drain regions 26 and the contact plugs 34 electrically connected to the source/drain regions 28 (FIG. 15B).

Next, over the inter-layer insulating film 30 with the contact plugs 32 buried in, a platinum (Pt) film is deposited by, e.g., CVD method.

Next, by photolithography and dry etching, the platinum film is patterned to form the source lines 36 electrically connected to the source/drain regions 26 via the contact plugs and the lower electrodes 38 electrically connected to the source/drain regions 28 via the contact plugs 34 (FIG. 15C). The lower electrodes 38 have a rectangular shape elongated column-wise and are connected to the contact plugs 34 at the central parts (refer to FIG. 12).

Next, over the inter-layer insulating film 30 with the source lines 36 and the lower electrodes 38 formed on, a silicon oxide film is deposited by, e.g., CVD method, and the surface of the silicon oxide film is planarized by CMP method or other methods to form the inter-layer insulating film 40 of the silicon oxide film buried between the source lines 36 and the lower electrodes 38 (FIG. 15D).

Then, over the source lines 36, the lower electrodes 38 and the inter-layer insulating film 40, a 50 nm-thickness TiOₓ film, for example, is deposited by laser ablation method, so-gel method, sputtering method, MOCVD method or other methods to form the resistance memory layer 42 of TiOₓ film.

Then, over the resistance memory layer 42, a platinum film 44a is deposited by, e.g., CVD method (FIG. 15E).

Next, by photolithography and dry etching, the platinum film 44a is patterned to form the upper electrodes 44 of the platinum film 44a (FIG. 15F). The upper electrodes 44 are formed two above respective one lower electrode 38. Thus, two resistance memory elements 46 having the one lower electrodes 38 in common are formed adjacent to each other in the extending direction of the word lines WL (refer to FIG. 12).

Next, by, e.g., CVD method, a silicon oxide film is deposited, and the surface of the silicon oxide film is planarized by, e.g., CMP method to form the inter-layer insulating film 48 of the silicon oxide film.

Next, by photolithography and dry etching, contact holes down to the upper electrodes 44 of the resistance memory elements 46 are formed in the inter-layer insulating film 48.

Next, by, e.g., CVD method, a barrier metal and a tungsten film are deposited, and theses conductive films are etched back to form in the contact holes, the contact plugs electrically connected to the upper electrodes 44 of the resistance memory elements 46.

Next, over the inter-layer insulating film 48 with the contact plugs 50 buried in, a conductive film is deposited, and then the conductive film is patterned by photolithography and dry etching to form the bit lines 52 connected to the resistance memory elements 46 via the contact plugs 50 (FIG. 15G).

Then, upper-level interconnection layers are further formed as required, and the nonvolatile semiconductor memory device is completed.

As described above, according to the present embodiment, two resistance memory elements include a lower electrode in common, which allows the resistance memory elements to be downsized. For two resistance memory elements, one cell select transistor is provided, which allows the integration of the elements to be further improved.

### A Third Embodiment

The method of writing into the nonvolatile semiconductor memory device according to a third embodiment of the present invention will be explained with reference to FIG. 14. The same members of the present embodiment as those of the resistance memory elements and the nonvolatile semiconductor memory devices according to the first and the second embodiments shown in FIGS. 1 to 15G are represented by the same reference numbers not to repeat or to simplify their explanation.

In the present embodiment, another method of writing into the nonvolatile semiconductor memory device according to the second embodiment will be explained. In the method according to the second embodiment, the collective setting is made, and then the respective memory cells are written, but the method according to the present embodiment is for writing in only arbitrary memory cells, i.e., is a method which can made random accesses.

First, the resistance states of the resistance memory elements 12a, 12b included in one memory cell 10 are read. The method of reading the resistance states of the resistance memory elements 12a, 12b is as described in the second embodiment. In the method of writing into the nonvolatile semiconductor memory device according to the present embodiment, drive conditions for the rewriting are set corresponding to combinations of the resistance states of the resistance memory elements 12a, 12b included in one memory cell 10. To this end, it is necessary to read the resistance states of the resistance memory elements 12a, 12b.

Next, corresponding to combinations of the read resistance states of the resistance memory elements 12a, 12b, the rewriting is made by the four methods described below.

(1) When Both of the Resistance Memory Elements 12a, 12b are in the High Resistance State, to Rewrite One of Them into the Low Resistance State

When the resistance memory element 12a and the resistance memory element 12b are in the high resistance state, and the resistance memory element 12a alone is rewritten to the low resistance state, a prescribed voltage is applied to the word line WL1 to turn on the cell select transistor 14, and the source line SL1 is connected to a reference potential, e.g., 0 V, which is the ground potential.

Next, a voltage of V_{SET}+ΔV_{SET} is applied to the bit line BL11, and a voltage V_{SET}−ΔV_{SET} is applied to the bit line BL12. A voltage V_{SET} is a voltage necessary to set the resistance memory elements 12 (set voltage), and a ΔV_{SET} is a voltage which satisfies 2ΔV_{SET}<V_{RESET}.

Thus, the voltage of V_{SET}+ΔV_{SET}, which is higher than the set voltage, is applied to the resistance memory element 12a, and the resistance memory element 12a is switched from the high resistance state to be set in the low resistance state. On the other hand, the voltage to be applied to the resistance memory element 12b is the voltage (V_{SET}−ΔV_{SET}), which is lower than the set voltage, and the resistance memory element 12b is retained in the high resistance state. The voltage between the bit line BL11 and the bit line BL12 is 2ΔV_{SET}, which is lower than the reset voltage V_{RESET}, and the adjacent memory cells are not disturbed. Thus, the resistance memory element 12a can be written into the low resistance state.

When the resistance memory elements 12b alone is rewritten into the low resistance state with the resistance memory elements 12a and the resistance memory element 12b being in the high resistance state, the voltage to be applied to the bit line BL11 and the voltage to be applied to the bit line BL12 may be exchanged.

(2) When Both of the Resistance Memory Elements 12a, 12b are in the Low Resistance State, to Rewrite One of Them into the High Resistance State

When the resistance memory element 12a and the resistance memory element 12b are in the low resistance state, and the resistance memory element 12a along is written into the high resistance state, first the prescribed voltage is applied to the word line WL1 to turn on the cell select transistor 14, and the source line SL1 is connected to the reference potential, e.g., 0 V, which is the ground potential.

Then, the voltage of V_{RESET}+ΔV_{RESET} is applied to the bit line BL11, and the voltage of V_{RESET}−ΔV_{RESET} is applied to the bit line BL12. The voltage V_{RESET} is a voltage necessary to reset the resistance memory element 12 (reset voltage), and the ΔV_{RESET} is a voltage which satisfies 2ΔV_{RESET}<V_{RESET}.

Thus, to the resistance memory element 12a, the voltage of V_{RESET}+ΔV_{RESET}, which is higher than the reset voltage, is applied, and the resistance memory element 12a is switched from the low resistance state to be reset in the high resistance state. On the other hand, the voltage to be applied to the resistance memory element 12b is the voltage (V_{RESET}−ΔV_{RESET}), which is lower than the reset voltage, and the resistance memory element 12b is retained in the low resistance state. The voltage between the bit line BL11 and the bit line BL12 is 2ΔV_{RESET}, which is lower the reset voltage V_{RESET}, and the adjacent memory cells are not disturbed. Thus, the resistance memory element 12a can be written into the high resistance state.

When the resistance memory element 12b alone is rewritten into the high resistance state with the resistance memory element 12a and the resistance memory element 12b being in the low resistance state, the voltage to be applied to the bit line BL11 and the voltage to be applied to the bit line BL12 may be exchanged.

(3) When One of the Resistance Memory Elements 12a, 12b is in the High Resistance State, and the Other is in the Low Resistance State, to Rewrite the Resistance Memory Elements in the Low Resistance State into the High Resistance State

When the resistance memory element 12a is rewritten into the high resistance state with the resistance memory element 12a being in the low resistance state and the resistance memory element 12b being in the high resistance state, first, the prescribed voltage is applied to the word line WL1 to turn on the cell select transistor 14, and the source line SL1 is connected to the reference potential, e.g., 0 V, which is the ground potential.

Next, the voltage of V_{RESET}+ΔV_{RESET} is applied to the bit lines BL1, BL12.

Thus, the voltage of V_{RESET}+ΔV_{RESET}, which is higher than the reset voltage, is applied, and the resistance memory element 12a is switched from the low resistance state to be set in the high resistance state. On the other hand, the voltage of V_{RESET}+ΔV_{RESET}, which is higher than the reset voltage is applied also to the resistance memory element 12b, but the resistance memory element 12b, which has been reset state, is retained in the high resistance state. The voltage between the bit line BL11 and the bit line BL12 is 0 V, and the adjacent memory cells are not disturbed. Thus, the resistance memory element 12a can be written into the high resistance state.

The above is the same when the resistance memory element 12a is in the high resistance state, the resistance memory element 12b being in the low resistance state, and the resistance memory element 12b is rewritten into the high resistance state.

(4) When One of the Resistance Memory Elements 12a, 12b is in the High Resistance State, and the Other is in the Low Resistance State, to Rewrite the Resistance Memory Element in the High Resistance State into the Low Resistance State

When the resistance memory element 12a is rewritten into the low resistance state with the resistance memory element 12a being in the high resistance state and the resistance memory element 12b being in the low resistance state, the prescribed voltage is applied to the word line WL1 to turn on the cell select transistor 14, and the source line SL1 is connected to the reference potential, e.g., 0 V, which is the ground potential. The voltage of V_{RESET}+ΔV_{RESET} is applied to the bit lines BL11, BL12.

Thus, to the resistance memory element 12b, the voltage of V_{RESET}+ΔV_{RESET}, which is higher than the reset voltage, is applied, and the resistance memory element 12b is switched from the low resistance state to the high resistance state. On the other hand, also to the resistance memory element 12a, the voltage of V_{RESET}+ΔV_{RESET}, which is higher than the reset voltage is applied, but the resistance memory element 12a, which has been reset state, is retained in the high resistance state. At this time, the voltage between the bit lines BL11 and the bit line BL12 is 0 V, and the adjacent memory cells are not disturbed.

Next, to the word line WL1, the prescribed voltage is applied to turn on the cell select transistor 14, and the source line SL1 is connected to the reference potential, e.g., 0 V, which is the ground potential. The voltage of V_{SET}+ΔV_{SET} is applied to the bit lines BL11, BL12.

Thus, to the resistance memory elements 12a, 12b, the voltage of V_{SET}+ΔV_{SET}, which is higher than the set voltage, and the resistance memory elements 12a, 12b are switched form the high resistance state to be set in the low resistance state. At this time, the voltage between the bit line BL11 and the bit line BL12 is 0 V, and the adjacent memory cells are not disturbed.

Thus, the resistance memory element 12a can be written into the low resistance state.

The above is the same when the resistance memory element 12b is rewritten into the low resistance state when the resistance memory element 12a is in the low resistance state, and the resistance memory element 12b is in the high resistance state.

As described above, according to the present embodiment, the writing can be made in arbitrary memory cells without disturbing un-selected memory cells.

### A Fourth Embodiment

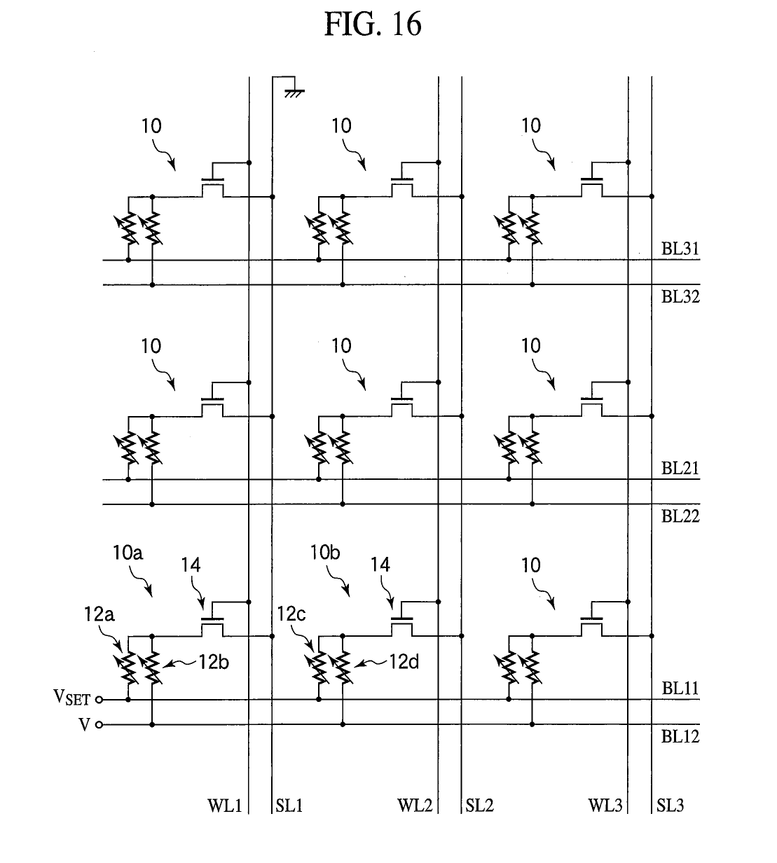

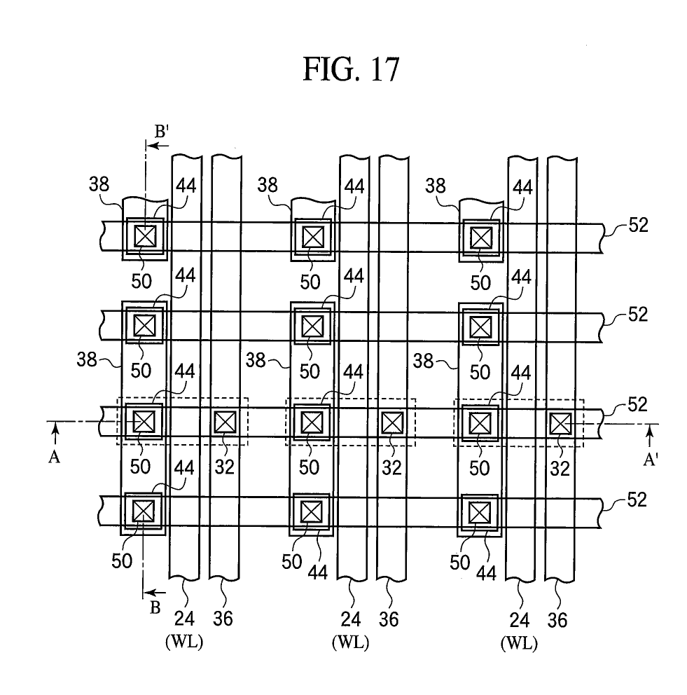

The method of writing into the nonvolatile semiconductor memory device according to a fourth embodiment of the present invention will be explained with reference to FIGS. 14 and 16. The same members of the present embodiment as those of the resistance memory element and the nonvolatile semiconductor memory device according to the first and the second embodiments shown in FIGS. 1 to 15G are represented by the same reference numbers not to repeat or to simplify their explanation.

FIG. 16 is a circuit diagram showing the method of writing into the nonvolatile semiconductor memory device according to the present embodiment.

In the present embodiment, another method of writing into the nonvolatile semiconductor memory device according to the second embodiment will be explained. In the method according to the second embodiment, the collective resetting is made, and then the respective memory cells are written. The method according to the present embodiment, however, is a method for writing arbitrary memory cells, i.e., a method which can make random accesses.

First, the rewriting operation from the high resistance state to the low resistance state, i.e., the setting operation will be explained. The resistance memory element to be rewritten is the resistance memory element 12a of the memory cell 10a connected to the word line WL1 and the bit line BL11 (see FIG. 16).

First, a prescribed voltage is applied to the word line WL1 to turn on the cell select transistor 14. The source line SL1 to which the memory cell 10a including the resistance memory element 12a to be rewritten is connected is connected to a reference potential, e.g., 0 V, which is the ground potential. The word lines WL2, WL3, . . . , the bit lines BL21, BL22, BL31, BL32, . . . and the source lines SL2, SL3, . . . connected to the un-selected cells are floating.

Next, to the bit line BL11, a bias voltage which is equal to or a little higher than a voltage necessary for setting the resistance memory element 12a (set voltage V_{SET}) is applied. For the resistance memory element having the characteristics shown in, e.g., FIG. 6, the bias voltage of, e.g., about 2 V is applied. The bit lines BL21, BL22, BL31, BL32, . . . of the un-selected cells are floating. The voltage to be applied to the bit line BL12 will be described later.

Thus, a current path to the source line SL1 via the bit line BL11, the resistance memory element 12a and the cell select transistor 14 is formed, and the applied voltage is divided to the resistance memory element 12a and the cell select transistor 14 corresponding to a resistance value R_{H} of the resistance memory element 12a and a channel resistance R_{CS} of the cell select transistor 14.

At this time, because of the resistance value R_{H} of the resistance memory element 12a, which is sufficiently large in comparison with the channel resistance R_{CS} of the cell select transistor, most of the bias voltage is applied to the resistance memory element 12a. Thus, the resistance memory element 12a is changed from the high resistance state to the lower resistance state.

Then, the bias voltage to be applied to the bit line BL11 is returned to zero, and then, the voltage to be applied to the word line WL1 is turned off. The setting operation is completed.

In the nonvolatile semiconductor memory device according to the second embodiment, in which the resistance memory elements 12a, 12b are connected to one cell select transistor 14, the disturbance to other memory cells via the resistance memory elements 12 (the resistance memory element 12b in the above) parallelly connected to the resistance memory element 12 to be rewritten (the resistance memory element 12a in the above) must be watched.

As a method for preventing such disturbance, it will be considered to boost the voltage of the bit line BL (the bit line BL12 in the above) to which the resistance memory element 12 (the resistance memory element 12b in the above) parallelly connected to the resistance memory element 12 to be rewritten (the resistance memory element 12a in the above). This method will be explained with reference to FIG. 16.

To the bit line BL11, the sett voltage V_{SET} is applied, and to the bit line BL12, a voltage V which is lower than a voltage necessary to reset the resistance memory element 12 (reset voltage V_{RESET}) is applied. Thus, the resistance memory element 12a is set in the low resistance state, and the resistance state of the resistance memory element 12b is not changed.

At this time, when another memory cell 10b connected to the bit lines BL11, BL12 is noted, a voltage corresponding to a potential difference between the bit lines BL11, BL12 (=V_{SET}−V) is applied also to the serially connected resistance memory elements 12c, 12d.

When the voltage between the bit lines BL11, BL12 (V_{SET}−V)/2 is below the reset voltage V_{RESET} (that is, (V_{SET}−V)/2<V_{RESET}), irrespective of the resistance states of the resistance memory elements 12c, 12d, a voltage which exceeds the reset voltage V_{RESET} are not applied to any of the resistance memory elements 12c, 12d, and no disturbance takes place.

When the half value of the voltage between the bit lines BL11, BL12 (V_{SET}−V)/2 is not less than the reset voltage V_{RESET} (that is, (V_{SET}−V)/2≧V_{RESET}), with both of the resistance memory elements 12c, 12d being in the high resistance state, a voltage which exceeds the set voltage V_{SET} is not applied to any of the resistance memory elements 12c, 12d, and no disturbance takes place. With one of the resistance memory elements 12c, 12d being in the high resistance state, and the other being in the low resistance state, the applied voltage is mainly divided to the resistance memory element 12 in the high resistance, but at this time as well, a voltage which exceed the set voltage V_{SET} is not applied, and no disturbance takes place.

When both of the resistance memory elements 12c, 12d are in the low resistance state, with V_{SET}−V≧2V_{RESET}, a voltage which exceeds V_{RESET} is applied to both of the resistance memory elements 12c, 12d, and the resistance states of the resistance memory elements 12c, 12d are changed (disturbances take place). In other words, with V_{SET}−V<2V_{RESET}, no disturbance takes place. That is, a voltage V which satisfies the relationship V>V_{SET}−2V_{RESET} is applied, whereby the disturbance can be prevented.

To summarize the above, a voltage V which satisfies the following relational expressions is applied to the bit line BL12, whereby the disturbance in the un-selected cells can be prevented.

V<V_{SET}+2V_{RESET}

V>V_{SET}−2V_{RESET}

To satisfy the above-described relationships, it is necessary that the resistance memory elements 12 has the relationship V_{SET}<3V_{RESET}. In the typical resistance memory element, as shown in, e.g., FIG. 6, the set voltage V_{SET} is a little less than twice the reset voltage V_{RESET}, which sufficiently satisfies the above-described relational expressions.

Next, the rewriting operation from the low resistance state to the high resistance state, i.e., the resetting operation will be explained. The resistance memory element to be rewritten is the resistance memory element 12a of the memory cell 10a connected to the word line WL1 and the bit line BL 11 (see FIG. 16).

First, a prescribed voltage is applied to the word line WL1 to turn on the cell select transistor 14. The source line SL1 to which the memory cell 10a including the resistance memory element 12a to be rewritten is connected is connected to a reference potential, e.g., 0 V, which is the ground potential. The word lines WL2, WL3, . . . , the bit lines BL21, BL22, BL31, BL32, . . . and the source lines SL2, SL3, . . . connected to the un-selected cells are floating.

Next, to the bit line BL11, a bas voltage which is equal to or a little higher than the voltage necessary for resetting the resistance memory element 12a (reset voltage V_{RESET}) is applied. For the resistance memory element having the characteristics shown in, e.g., FIG. 6, the bias voltage of, e.g., about 1 V is applied. The bit lines BL21, BL22, BL31, BL32, . . . connected to the un-selected cells are floating. The voltage to be applied to the bit line BL12 will be described later.

Thus, a current path to the source line SL1 via the bit line BL11, The resistance memory element 12a and the cell select transistor 14 is for formed, and the applied bias voltage is divided to the resistance memory element 12a and the cell select transistor 14 corresponding to a resistance value R_{L} of the resistance memory element 12a and a channel resistance R_{CS} of the cell select transistor 14.

At this time, because of the channel resistance R_{CS} of the cell select transistor 14, which is sufficiently smaller than the resistance value R_{L} of the resistance memory element 12a, most of the applied bias voltage is applied to the resistance memory element 12a. Thus, the resistance memory element 12a is changed from the low resistance state to the high resistance state.

In the resetting process, the instant the resistance memory element 12a has been changed to the high resistance state, substantially all the bias voltage is divided to the resistance memory element 12a, and it is necessary to prevent the resistance memory element 12a from being again set with this bias voltage. To this end, the bias voltage to be applied to the bit line BL11 must be lower than the voltage necessary for the setting (set voltage V_{SET}).

That is, in the resetting process, the gate voltage of the cell select transistor 14 must be adjusted so that the channel resistance R_{CS} of the cell select transistor 14 is sufficiently smaller than the resistance value R_{L} of the resistance memory element 12a while the bias voltage to be applied to the bit line BL11 is set at a voltage of not less than the voltage necessary for the resetting and less than the voltage necessary for the setting.

Next, the bias voltage to be applied to the bit line BL11 is returned to zero, and then the voltage to be applied to the word line WL1 is turned off. The resetting operation is completed.

In the resetting operation as well, the mechanism of the disturbance is basically the same as that of the setting operation. Because of the reset voltage V_{RESET} lower than the set voltage V_{SET}, the disturbance does not easily take place in comparison with that in the setting operation. That is, a voltage V which satisfies the following relational expression is applied to the bit line BL12, whereby the disturbance in the un-selected cells can be prevented.

V<V_{SET}+2V_{RESET}

In the nonvolatile semiconductor memory device according to the second embodiment, as shown in FIG. 14, the word lines WL and the source lines SL are arranged column-wise, and the memory cells 10 connected to one word line (e.g., WL1) are connected to the same source line (e.g., SL1). Accordingly, in the resetting operation described above, when a plurality of the bit lines (e.g., BL11-BL32) are simultaneously driven, a plurality of the memory cells 10 connected to the selected word line (e.g., WL1) can be also reset at once.

As described above, according to the present embodiment, the writing can be made in arbitrary memory cells without disturbing non-selected cells.

### A Fifth Embodiment

The nonvolatile semiconductor memory device and the method of writing into the same according to a fifth embodiment of the present invention will be explained with reference to FIGS. 17 to 19.

The same members of the present embodiment as those of the nonvolatile semiconductor memory device and the method of writing into the same according to the first to the fourth embodiment shown in FIGS. 1 to 16 are represented by the same reference numbers not to repeat or to simplify their explanation.

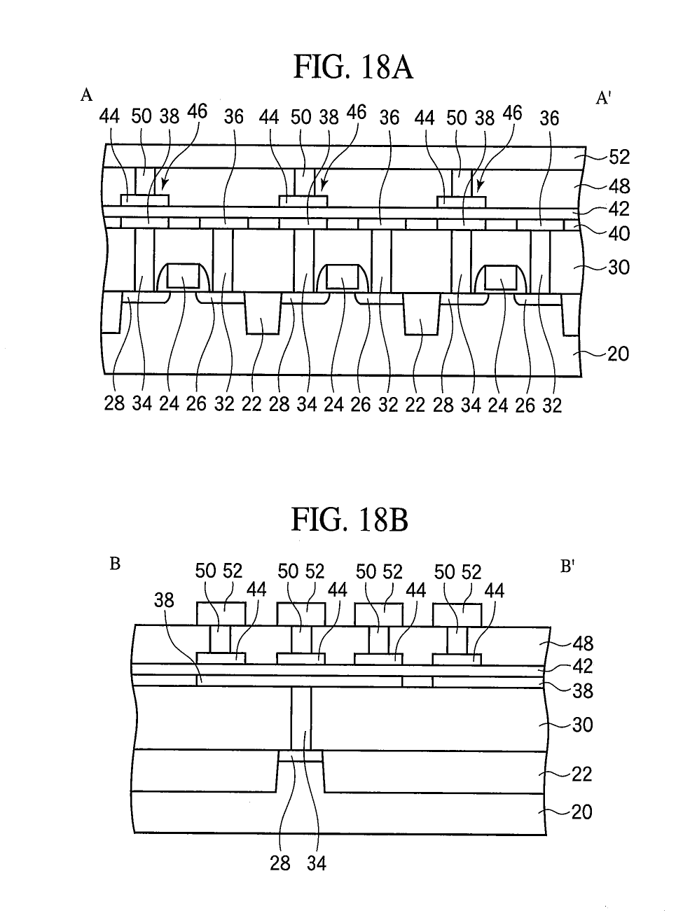

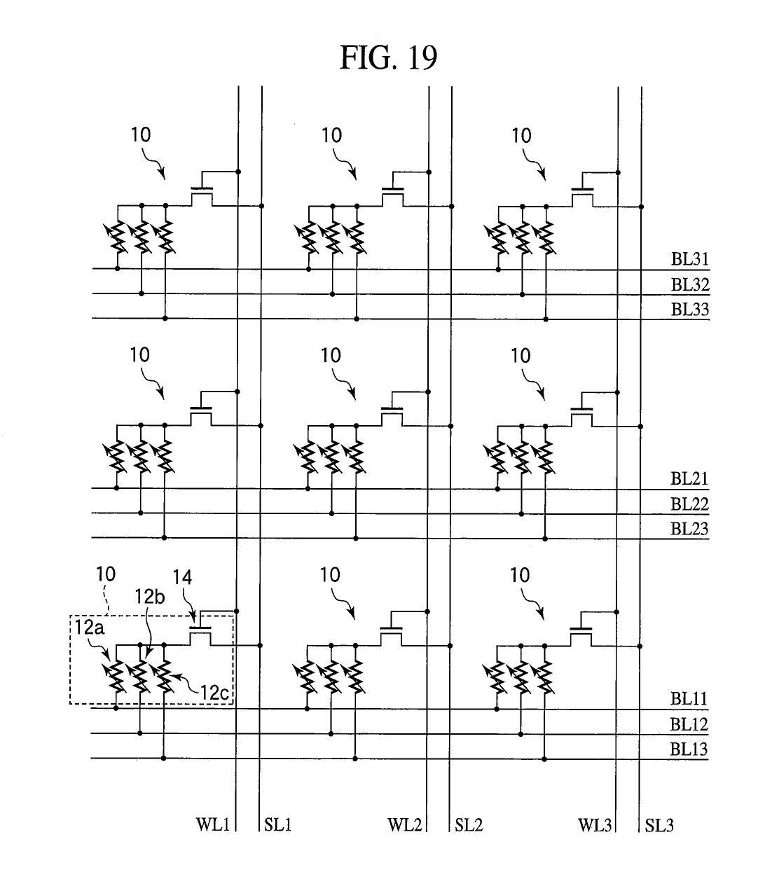

FIG. 17 is a plan view showing the structure of the nonvolatile semiconductor memory device according to the present embodiment. FIGS. 18A and 18B are diagrammatic sectional views showing the structure of the nonvolatile semiconductor memory device according to the present embodiment. FIG. 19 is a circuit diagram showing the structure of the nonvolatile semiconductor memory device according to the present embodiment.

First, the structure of the nonvolatile semiconductor memory device according to the present embodiment will be explained with reference to FIGS. 17, 18A and 18B. FIG. 18A is the sectional view along the line A-A′ in FIG. 17, and FIG. 18B is the sectional view along the line B-B′ in FIG. 17.

As shown in FIGS. 17, 18A and 18B, in a silicon substrate 20, a device isolation film 22 for defining device regions is formed. In the device regions of the silicon substrate 20, cell select transistors each including a gate electrode 24 and source/drain regions 26, 28 are formed.

As shown in FIG. 17, the gate electrodes 24 function also as word lines WL commonly connecting the gate electrodes 24 of the cell select transistors adjacent to each other column-wise (vertically in the drawing).

Over the silicon substrate 20 with the cell select transistors formed on, an inter-layer insulating film 30 with contact plugs 32 electrically connected to the source/drain regions 26 and contact plugs 34 electrically connected to the source/drain regions 28 buried in is formed. Over the inter-layer insulating film 30, source lines 36 electrically connected to the source/drain regions 26 via the contact plugs 32 and lower electrodes 38 electrically connected to the source/drain regions 28 via the contact plugs 34 are formed. The lower electrodes 38 have a rectangular shape elongated column-wise and are connected to the contact plugs 34 at the centers thereof (refer to FIG. 17).

Over the inter-layer insulating film 30 except that in the regions where the source lines 36 and the lower electrodes 38 formed on, an inter-layer insulating film 40 is formed. Thus, the surfaces of the source lines 36, the lower electrodes 38 and the inter-layer insulating film 40 are planarized.

Over the source lines 36, the lower electrodes 38 and the inter-layer insulating film 40, a resistance memory layer 42 is formed. Over the resistance memory layer 42, upper electrodes 44 are formed. The upper electrodes 44 are formed three above each lower electrode 38. Thus, three resistance memory elements 46 including one lower electrode 38 in common are formed respectively in the region where the lower electrode 38 is formed.

Over the resistance memory elements 46, an inter-layer insulating film 48 is formed. In the inter-layer insulating film 48, contact plugs 50 electrically connected to the upper electrodes 44 of the resistance memory elements 46 are buried.

Over the inter-layer insulating film 48 with the contact plugs 50 buried in, bit lines 52 connected to the upper electrodes 44 of the resistance memory elements 46 via the contact plugs 50 and extended row-wise are formed.

As described above, the nonvolatile semiconductor memory device according to the present embodiment is characterized mainly in that the lower electrodes 38 are common among the resistance memory elements 46 adjacent to each other column-wise. Three resistance memory elements commonly including the lower electrode 38 are connected to one select transistor.

The electric characteristics of the resistance memory elements 46 are defined by the filament shaped property changed region formed in the resistance memory layer 42. Accordingly, with three upper electrodes 44 provided for one lower electrode 38, filament shaped property changed regions are formed between the upper electrode 44 and the three lower electrodes 38 to be memory regions, whereby three resistance memory elements 46 can function. This permits the elements to be downsized. In the nonvolatile semiconductor memory device according to the present embodiment, one cell select transistor may be formed for three resistance memory elements, which can further improve the integration of the elements.

FIG. 19 is the circuit diagram of the nonvolatile semiconductor memory device according to the present embodiment shown in FIGS. 17, 18A and 18B. As shown in FIG. 19, one memory cell 10 includes one cell select transistor 14 and three resistance memory elements 12a, 12b, 12c. The cell select transistor 14 has the source terminal connected to the source lines SL (SL1) and the gate terminal connected to the word lines WL (WL1). The resistance memory elements 12a, 12b, 12c have one terminals connected to the drain terminal of the cell select transistor 14 and the other terminals connected respectively to different bit lines BL (BL11, BL12, BL13). Such memory cells 10 are formed adjacent to each other column-wise (vertically in the drawing) and row-wise (transversely in the drawing).

A plurality of word lines WL1, WL2, WL3, . . . are arranged column-wise and form common signal lines which are common for the memory cells 10 arranged column-wise. Source lines SL1, SL2, . . . are arranged column-wise and form signal lines which are common among the memory cells 10 arranged column-wise.

A plurality of bit lines BL11, BL12, BL13, BL21, BL22, BL23, BL31, BL32, BL33, . . . are arranged row-wise (transversely in the drawing) and form signal lines which are common among the memory cells arranged row-wise.

The methods of writing into and reading the nonvolatile semiconductor memory device according to the present embodiment are basically the same as those of the second to the fourth embodiments. That is, three bit lines connected to one memory cell 10 are divided in a group of the bit line (e.g., bit line BL11) to be connected to the resistance memory element to be rewritten (e.g., the resistance memory element 12a) and a group of the other two resistance memory elements (e.g., the resistance memory elements 12b, 12c), and the voltage described in the above-described embodiments may be applied to the respective groups.

As described above, according to the present embodiment, each lower electrode is common among three resistance memory elements, which permits the resistance memory element to be downsized. One cell select transistors is provided for three resistance memory elements, which permits the integration of the elements to be further improved.

### Modified Embodiments

The present invention is not limited to the above-described embodiments and can cover other various modifications.

For example, in the above-described embodiments, the resistance memory element 54 including the resistance memory layer of TiOₓ is used, but the resistance memory layer of the resistance memory element is not limited to this. The resistance memory materials applicable to the invention of the present application are TiOₓ, NiOₓ, YOₓ, CeOₓ, MgO, ZnOₓ, WOₓ, NbOₓ, TaOₓ, CrOₓ, MnOₓ, AlOₓ, VOₓ, SiOₓ, etc. Oxide materials containing a plurality of metals and semiconductor atoms, such as Pr₁₋ₓCaₓMnO₃, La₁₋ₓCaₓMnO₃, SrTiO₃, etc., can be also used. These resistance memory materials may be used singly or in layer structures.

In the above-described embodiments, the upper electrodes and the lower electrodes are formed of platinum, but the material of the electrodes is not limited to this. The electrode materials applicable to the invention of the present application are, e.g., Ir, W, Ni, Au, Cu, Ag, Pd, Zn, Cr, Al, Mn, Ta, Si, TaN, TiN, Ru, ITO, NiO, IrO, SrRuO, CoSi₂, WSi₂, NiSi, MoSi₂, TiSi₂, Al—Si, Al—Cu, Al—Si—Cu, etc.

In the first embodiment described above, one upper electrode is provided for two lower electrodes, in the second to the fourth embodiments, two upper electrodes are provided for one lower electrode, and in the fifth embodiment, three upper electrodes are provided for one lower electrode. However, the number combinations of the upper electrode and the lower electrode are not limited to them. A plurality of electrodes to be arranged may be upper electrodes or lower electrodes, and the number of them is not limited to 2 or 3.

In the method of writing into the nonvolatile semiconductor memory device according to the second embodiment, a sector containing a memory cell to be rewritten is reset at once, and then, the resistance memory element to be set is written. However, a sector containing a memory cell to be rewritten may be set at once, and then, the resistance memory element to be reset may be written. Generally, the resetting takes longer time than the setting, and the collective resetting is more advantageous in terms of the writing time than the collective setting.

The foregoing is considered as illustrative only of the principles of the present invention. Further, since numerous modifications and changes will readily occur to those skilled in the art, it is not desired to limit the invention to the exact construction and applications shown and described, and accordingly, all suitable modifications and equivalents may be regarded as falling within the scope of the invention in the appended claims and their equivalents.

What is claimed is:

1. A semiconductor memory device comprising:
a resistance memory element including:
a common electrode;
a resistance memory layer which is formed on the common electrode and is switched between a high resistance state and a low resistance state by an application of a voltage; and
a plurality of discrete electrodes formed on the resistance memory layer,
wherein the resistance memory layer includes a plurality of memory regions for memorizing the high resistance state or the low resistance state between the common electrode and the plurality of discrete electrodes independently of each other.

2. The semiconductor memory device according to claim 1, further comprising:
a cell select transistor; and
a plurality of bit lines connected respectively to the plurality of discrete electrodes.

3. The semiconductor memory device according to claim 1, further comprising:
a plurality of cell select transistors connected respectively to the plurality of discrete electrodes; and
a bit line connected to the common electrode.

4. The semiconductor memory device according to claim 1, wherein
a gap between the plurality of discrete electrodes is larger than a distance equivalent to a film thickness of the resistance memory layer.

5. The semiconductor memory device according to claim 1, wherein
the common electrode is arranged above the plurality of discrete electrodes.

6. The semiconductor memory device according to claim 1, wherein
the resistance memory element is written by resetting the plurality of memory regions in the high resistance state at once; and then setting an arbitrary one of the plurality of memory regions in the low resistance state.

7. The semiconductor memory device according to claim 1, wherein
when a first memory region of the plurality of memory regions is rewritten into the low resistance state with the first memory region and a second memory region of the plurality of memory regions being in the high resistance state, the resistance memory element is written by applying a first voltage which is higher than a set voltage of the resistance memory element between the common electrode and a first discrete electrode of the plurality of discrete electrodes, applying a second voltage which is lower than the set voltage of the resistance memory element between the common electrode and a second discrete electrode of the plurality of discrete electrodes, and setting a potential difference between the first voltage and the second voltage lower than a reset voltage of the resistance memory element,

8. The semiconductor memory device according to claim 1, wherein
when a first memory region of the plurality of memory regions is rewritten into the high resistance state with the first memory region and a second memory region of the plurality of memory regions being in the low resistance state, the resistance memory element is written by applying a first voltage which is higher than a reset voltage of the resistance memory element between the common electrode and a first discrete electrode of the plurality of discrete electrodes, applying a second voltage which is lower than the reset voltage of the resistance memory element between the common electrode and a second discrete electrode of the plurality of discrete electrodes, and setting a potential difference between the first voltage and the second voltage smaller than the reset voltage of the resistance memory element.

9. The semiconductor memory device according to claim 1, wherein
when a first memory region of the plurality of memory regions is rewritten into the high resistance state with the first memory region being in the low resistance state and a second memory region of the plurality of memory regions being in the high resistance state, the resistance memory element is written by applying a voltage which is higher than or equal to a reset voltage of the resistance memory element respectively between the common electrode and a first discrete electrode of the plurality of discrete electrodes and between the common electrode and a second discrete electrode of the plurality of discrete electrodes.

10. The semiconductor memory device according to claim 1, wherein
when a first memory region of the plurality of memory regions is written into the low resistance state with the first memory region being in the high resistance state and a second memory region of the plurality of memory regions being in the low resistance state, the resistance memory element is written by applying a voltage which is higher than or equal to a reset voltage of the resistance memory element respectively between the common electrode and a first discrete electrode of the plurality of discrete electrodes and between the common electrode and a second discrete electrode of the plurality of discrete electrodes to thereby rewrite the second memory region into the high resistance state, and then applying a voltage which is higher than or equal to a set voltage of the resistance memory element respectively between the common electrode and the first discrete electrode and between the common electrode and the second discrete electrode to thereby rewrite the first memory region and the second memory region into the low resistance state.

11. The semiconductor memory device according to claim 1, wherein
the resistance memory element is written by applying a set voltage of the resistance memory element to that of the plurality of discrete electrodes, which is associated with that of the plurality of memory region into which the low resistance state is to be written, and applying to that of the plurality of discrete electrodes, which is associated with that of the plurality of memory regions, into which the low resistance state is not to be written a voltage V which satisfies relations:
V<V_{SET}+2V_{RESET} and V>V_{SET}−2V_{RESET}
wherein the set voltage of the resistance memory element is V_{SET}, and a reset voltage of the resistance memory element is V_{RESET}.

12. A method of writing into a semiconductor memory device comprising:
resetting a plurality of memory regions in a high resistance state at once; and
then setting an arbitrary one of the plurality of memory regions in a low resistance state,
wherein the semiconductor memory device includes a resistance memory element including a common electrode; a resistance memory layer which is formed on the common electrode and is switched between the high resistance state and the low resistance state by an application of a voltage; and a plurality of discrete electrodes formed on the resistance memory layer, wherein the resistance memory layer includes the plurality of memory regions for memorizing the high resistance state or the low resistance state between the common electrode and the plurality of discrete electrodes independently of each other.

13. The method of writing into a semiconductor memory device according to claim 12, wherein
when the arbitrary memory region is set in the low resistance state,
applying a first voltage which is higher than a set voltage of the resistance memory element between the discrete electrode associated with the arbitrary memory region and the common electrode;
applying a second voltage which is lower than the set voltage of the resistance memory element between the other discrete electrodes and the common electrode; and
setting a potential difference between the first voltage and the second voltage lower than a reset voltage of the resistance memory element.

14. The method of writing into a semiconductor memory device according to claim 12, wherein
when the plurality of memory regions is set in the low resistance state,
applying a voltage which is higher than or equal to the set voltage of the resistance memory element between the plurality of discrete electrodes and the common electrode.

15. A method of writing into a semiconductor memory device comprising:
when a first memory region is rewritten into a low resistance state with the first memory region and a second memory region being in a high resistance state,
applying a first voltage which is higher than a set voltage of a resistance memory element between a common electrode and a first discrete electrode;
applying a second voltage which is lower than the set voltage of the resistance memory element between the common electrode and a second discrete electrode; and
setting a potential difference between the first voltage and the second voltage lower than a reset voltage of the resistance memory element,
when the first memory region is rewritten into the high resistance state with the first memory region and the second memory regions being in the low resistance state,
applying a first voltage which is higher than a reset voltage of the resistance memory element between the common electrode and the first discrete electrode;
applying a second voltage which is lower than the reset voltage of the resistance memory element between the common electrode and the second discrete electrode; and
setting a potential difference between the first voltage and the second voltage smaller than the reset voltage of the resistance memory element,
when the first memory region is rewritten into the high resistance state with the first memory region being in the low resistance state and the second memory region being in the high resistance state,
applying a voltage which is higher than or equal to the reset voltage of the resistance memory element respectively between the common electrode and the first discrete electrode and between the common electrode and the second discrete electrode, and
when the first memory region is written into the low resistance state with the first memory region being in the high resistance state and the second memory region being in the low resistance state,
applying a voltage which is higher than or equal to the reset voltage of the resistance memory element respectively between the common electrode and the first discrete electrode and between the common electrode and the second discrete electrode to thereby rewrite the second memory region into the high resistance state; and
then applying a voltage which is higher than or equal to the set voltage of the resistance memory element respectively between the common electrode and the first discrete electrode and between the common electrode and the second discrete electrode to thereby rewrite the first memory region and the second memory region into the low resistance state,
wherein the semiconductor memory device includes the resistance memory element including the common electrode; a resistance memory layer which is formed on the common electrode and is switched between the high resistance state and the low resistance state by an application of a voltage; and the first and the second discrete electrodes formed on the resistance memory layer, wherein the resistance memory layer includes the first and the second memory regions for memorizing the high resistance state or the low resistance state between the common electrode and the first and the second discrete electrodes independently of each other.

16. A method of writing into a semiconductor memory device comprising:
applying a set voltage of a resistance memory element to that of a plurality of discrete electrodes, which is associated with that of a plurality of memory region into which a low resistance state is to be written; and
applying to that of the plurality of discrete electrodes, which is associated with that of the plurality of memory regions, into which the low resistance state is not to be written a voltage V which satisfies relations:
V<V_{SET}+2V_{RESET} and V>V_{SET}−2V_{RESET}
wherein the set voltage of the resistance memory element is V_{SET}, and a reset voltage of the resistance memory element is V_{RESET},
wherein the semiconductor memory device includes a resistance memory element including a common electrode; a resistance memory layer which is formed on the common electrode and is switched between the high resistance state and the low resistance state by an application of a voltage; and the plurality of discrete electrodes formed on the resistance memory layer, wherein the resistance memory layer includes the plurality of memory regions for memorizing the high resistance state or the low resistance state between the common electrode and the plurality of discrete electrodes independently of each other.
